(19) United States
(12) Patent Application Publication
(10) Pub. No.: US 2026/0280587 A1
(43) Pub. Date: Sep. 17, 2026

(54) PERMUTATIONS FOR A LOW-DENSITY PARITY CHECK CODE

(71) Applicant: QUALCOMM Incorporated, San Diego, CA (US)

(72) Inventors: Pinar SEN, San Diego, CA (US); Wei YANG, San Diego, CA (US); Thomas Joseph RICHARDSON, South Orange, NJ (US); Jing JIANG, San Diego, CA (US); Alessandro RISSO, San Diego, CA (US); Hobin KIM, San Diego, CA (US); Ming Ta LIN, San Jose, CA (US); Harsha ACHARYA, Santa Clara, CA (US)

(21) Appl. No.: 19/080,486

(22) Filed: Mar. 14, 2025

(51) Int. Cl. H03M 13/11

(52) U.S. Cl. CPC H03M 13/1165

(57) ABSTRACT

Various aspects of the present disclosure generally relate to wireless communication. In some aspects, a first network entity may encode first information to obtain encoded information, wherein the permutation pattern is associated with columns of a base graph for a low-density parity check code. The first network entity may modulate the encoded information to map the encoded information to one or more constellation symbols. The first network entity may transmit a signal that indicates second information that is based on the one or more constellation symbols. Numerous other aspects are described.

### FIELD OF THE DISCLOSURE

Aspects of the present disclosure generally relate to wireless communication and specifically relate to techniques, apparatuses, and methods associated with permutations for a low-density parity check code.

### INTRODUCTION

Wireless communication systems are widely deployed to provide various services, which may involve carrying or supporting voice, text, other messaging, video, data, or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, or device transmit power, among other examples). Such multiple-access RATs are supported by technological advancements that have been adopted in various telecommunication standards, which define common protocols that enable different wireless communication devices to communicate on a local, municipal, national, regional, or global level. An example telecommunication standard is New Radio (NR). NR, which also may be referred to as 5G, is part of a continuous mobile broadband evolution promulgated by the Third Generation Partnership Project (3GPP). As the demand for connectivity continues to increase, further improvements in NR may be implemented, and other RATs, such as 6G and beyond, may be introduced to enable new applications and facilitate new use cases.

To support use cases that may demand high data rates, high reliability, low latency, or low power consumption, channel coding may be used in a wireless communication system to ensure reliable and efficient communication. For example, channel coding generally involves an encoding operation performed at a transmitter to selectively add redundancy to transmitted data, and a decoding operation at a receiver where the additional redundancy is used to detect or correct errors that may occur during transmission or reception. For example, because wireless communication channels tend to be noisy or unreliable, data can be corrupted during transmission due to factors such as noise, interference, or channel fading, among other examples. When errors in transmitted data cannot be corrected at the receiver, the transmitted data may be lost or retransmissions may be performed to provide the correct data to the receiver. Accordingly, because lost data reduces reliability and retransmissions increase latency and power consumption, channel coding techniques are used in wireless communication systems to ensure that received data is the same as transmitted data. For example, channel coding techniques may use polar codes, Reed-Muller codes, repetition codes, or simplex codes for control channels or other channels with low to moderate payload sizes, and turbo codes or low density parity check (LDPC) codes for data channels or other channels that tend to have relatively larger payload sizes.

In this way, channel coding techniques may offer various performance improvements in wireless communication systems. For example, channel coding techniques provide error detection and error correction capabilities that may increase a likelihood that transmitted data is reliably received despite noise, interference, or fading conditions that may be present in a wireless channel. In addition, channel coding may reduce an error rate and increase reliability for wireless transmission, which may mitigate errors, reduce retransmissions, and improve overall throughput. Furthermore, although encoding and decoding operations may add some processing delay, efficient channel coding schemes may reduce the processing delay and the improved error detection and correction capabilities may reduce retransmissions, which reduces overall latency. Channel coding techniques may also extend wireless coverage because a network node may transmit data in a reliable manner over a longer distance or in a challenging radio environment, improve spectral efficiency by minimizing the impact that errors have on the use of available frequency spectrum, or improve energy efficiency at network nodes and user devices by supporting efficient encoding or decoding schemes or reducing retransmissions, among other examples.

### SUMMARY

The systems, methods, and devices of this disclosure each have several innovative aspects, no single one of which is solely responsible for the desirable attributes disclosed herein.

Some aspects described herein relate to a first network entity. The first network entity may include a processing system. The processing system may be configured to encode, based on a permutation pattern, first information to obtain encoded information, wherein the permutation pattern is associated with columns of a base graph for a low-density parity check code. The processing system may be configured to modulate the encoded information to map the encoded information to one or more constellation symbols. The processing system may be configured to transmit a signal that indicates second information that is based on the one or more constellation symbols.

Some aspects described herein relate to a first network entity. The first network entity may include a processing system. The processing system may be configured to receive a signal that indicates first information associated with one or more constellation symbols. The processing system may be configured to demodulate, based on the one or more constellation symbols, the first information to obtain encoded information. The processing system may be configured to decode, based on a permutation pattern, the encoded information to obtain second information, wherein the permutation pattern is associated with columns of a base graph for a low-density parity check code.

Some aspects described herein relate to a method of wireless communication performed by a first network entity. The method may include encoding, based on a permutation pattern, first information to obtain encoded information, wherein the permutation pattern is associated with columns of a base graph for a low-density parity check code. The method may include modulating the encoded information to map the encoded information to one or more constellation symbols. The method may include transmitting a signal that indicates second information that is based on the one or more constellation symbols.

Some aspects described herein relate to a method of wireless communication performed by a first network entity. The method may include receiving a signal that indicates first information associated with one or more constellation symbols. The method may include demodulating, based on the one or more constellation symbols, the first information to obtain encoded information. The method may include decoding, based on a permutation pattern, the encoded information to obtain second information, wherein the permutation pattern is associated with columns of a base graph for a low-density parity check code.

Some aspects described herein relate to an apparatus for wireless communication. The apparatus may include means for encoding, based on a permutation pattern, first information to obtain encoded information, wherein the permutation pattern is associated with columns of a base graph for a low-density parity check code. The apparatus may include means for modulating the encoded information to map the encoded information to one or more constellation symbols. The apparatus may include means for transmitting a signal that indicates second information that is based on the one or more constellation symbols.

Some aspects described herein relate to an apparatus for wireless communication. The apparatus may include means for receiving a signal that indicates first information associated with one or more constellation symbols. The apparatus may include demodulating, based on the one or more constellation symbols, the first information to obtain encoded information. The apparatus may include means for decoding, based on a permutation pattern, the encoded information to obtain second information, wherein the permutation pattern is associated with columns of a base graph for a low-density parity check code.

Some aspects described herein relate to a non-transitory computer-readable medium having code stored thereon. The code, when executed by a network entity, may cause the network entity to encode, based on a permutation pattern, first information to obtain encoded information, wherein the permutation pattern is associated with columns of a base graph for a low-density parity check code. The code, when executed by a network entity, may cause the network entity to modulate the encoded information to map the encoded information to one or more constellation symbols. The code, when executed by a network entity, may cause the network entity to transmit a signal that indicates second information that is based on the one or more constellation symbols.

Some aspects described herein relate to a non-transitory computer-readable medium having code stored thereon. The code, when executed by a network entity, may cause the network entity to receive a signal that indicates first information associated with one or more constellation symbols. The code, when executed by a network entity, may cause the network entity to demodulating, based on the one or more constellation symbols, the first information to obtain encoded information. The code, when executed by a network entity, may cause the network entity to decode, based on a permutation pattern, the encoded information to obtain second information, wherein the permutation pattern is associated with columns of a base graph for a low-density parity check code.

Aspects generally include a method, apparatus, system, computer program product, non-transitory computer-readable medium, user equipment, base station, network entity, network node, wireless communication device, or processing system as substantially described herein with reference to and as illustrated by the drawings and specification.

The foregoing broadly outlines example features and example technical advantages of examples according to the disclosure. Additional example features and example advantages are described hereinafter.

### BRIEF DESCRIPTION OF THE DRAWINGS

FIG. 1 is a diagram illustrating an example environment in which apparatuses or methods described herein may be implemented.

FIG. 2 is a diagram illustrating an example of a wireless communication network.

FIG. 3 is a diagram illustrating an example disaggregated network node architecture.

FIG. 4 is a diagram illustrating an example of communication using low-density parity check (LDPC) codes.

FIG. 5 is a diagram illustrating an example of an LDPC base matrix and an LDPC base graph.

FIG. 6 is a diagram illustrating an example of a parity check matrix associated with an LDPC code.

FIG. 7 is a diagram illustrating an example of lifting for an LDPC code.

FIG. 8 is a diagram illustrating an example of interleaving.

FIG. 9 is a diagram of an example associated with permutations for an LDPC code.

FIG. 10 is a diagram of an example associated with a permutation of a base graph for an LDPC code.

FIG. 11 is a diagram illustrating an example of redundancy versions.

FIG. 12 is a diagram illustrating an example of a Tx chain and an Rx chain per dimension in a probabilistic amplitude shaping system.

FIG. 13 is a diagram illustrating an example process performed, for example, at a first network entity or an apparatus of a first network entity.

FIG. 14 is a diagram illustrating an example process performed, for example, at a first network entity or an apparatus of a first network entity.

FIG. 15 is a diagram of an example apparatus for wireless communication.

FIG. 16 is a diagram of an example apparatus for wireless communication.

### DETAILED DESCRIPTION

Low density parity check (LDPC) codes are linear block codes that may be used to provide forward error correction capabilities in a communication system with a performance that approaches channel capacity. The performance may be achieved under an iterative belief propagation decoding scheme, also known as message-passing decoding, which has a linear complexity associated with an LDPC code block length. In particular, LDPC codes are defined or represented according to a sparse parity check matrix (PCM) that typically has a low density of entries with a value of 1. From a transmitter perspective, the transmitter (or LDPC encoder) multiplies one or more systematic bits or information bits by a PCM to generate a code block (or codeword). The sparse PCM generally includes a systematic submatrix and a parity submatrix. The parity submatrix may be inverted to compute a parity vector used to encode an LDPC code. In some cases, as a result of the sparseness, the parity submatrix portion of the PCM may have a structure that makes the complexity of the parity submatrix inversion prohibitive as code block length increases. Accordingly, LDPC codes may utilize an accumulative chain structure, also known as a degree-2 chain structure, to simplify the encoding. Furthermore, in some cases, an LDPC code may be quasi-cyclic. For example, as described herein, a quasi-cyclic LDPC (QC-LDPC) code is associated with a base graph and lifting values that provide a compact PCM representation, which enables efficient encoding and high parallelism in a decoder architecture.

Systematic bit priority mapping (SBPM) is a technique to map systematic bits of a communication to the most significant bits of each modulated symbol of the communication. This increases reliability due to an increased likelihood of correct demodulation of the systematic bits because the most significant bits (e.g., the most significant bit, or one or more most significant bits) of the modulated symbol have increased protection against errors as compared to the least significant bits (e.g., the least significant bit, or one or more least significant bits) of the modulated symbol when using conventional modulation constellations, such as phase-shift keying (PSK) or quadrature amplitude modulation (QAM). For example, even if a receiver incorrectly demodulates a modulated symbol, that incorrect demodulation is likely to correspond to a constellation point, in a constellation diagram for the conventional modulation scheme, that is near the correct constellation point and that has one or more most significant bits in common with the correct constellation point. SBPM may be referred to as a bit-to-modulation mapping technique. For example, SBPM may be a technique for mapping coded bits to modulation constellation symbols for over-the-air transmission.

In some aspects, block interleaving (e.g., SBPM interleaving) may be performed using a technique called write by row, read by column. Using this technique, bits may be obtained from a circular buffer as part of a rate matching process, with a starting bit determined based at least in part on a redundancy version, of the communication, to be transmitted. As the bits are obtained, those bits may be written to blocks across a first row, where each bit is placed in a different column corresponding to a different symbol. After the first row is filled, bits may be written to blocks across a second row, and so on. The starting bit and a set of subsequent bits of the circular buffer may be systematic bits, and may be followed by parity bits. As a result, the first one or more rows may include systematic bits, and the last one or more rows may include parity bits.

Because the first row(s) correspond to more significant bits (e.g., most significant bits (MSBs)) of the modulated symbol and the last row(s) correspond to less significant bits (e.g., least significant bits (LSBs)) of the modulated symbol, this technique may map systematic bits (e.g., some, most, or all of the systematic bits, depending on a starting bit in the circular buffer) to the most significant bit(s) of the modulated symbol, thereby increasing reliability, as described above. After all of the coded bits are written to the blocks, referred to as interleaving, those interleaved bits are read from the blocks down a first column as input to a modulation process to modulate those coded bits in a modulated symbol. After modulation, the coded bits in the first column will be represented as a first modulated symbol, the coded bits in a second column will be represented as a second modulated symbol, and so on. In some aspects, the interleaving or the modulation may be performed to first map the modulated symbols to a layer (e.g., a multiple-input multiple-output (MIMO) layer), then map the modulated symbols to a frequency, and then map the modulated symbols to time. In this way, protection from burst errors may be enhanced.

As an example, an SBPM scheme may enable a transmitter to map the systematic portion of coded bits (e.g., LDPC coded bits) to the MSB of a modulation constellation, and to map the non-systematic portion to the LSB of the modulation constellation. Without applying SBPM, each variable node in the base graph may experience, on average, the same channel conditions or reliabilities. As a result of applying SBPM, copies of the same variable node in a base graph may be associated with similar channel reliabilities and different variable nodes in the base graph may experience different channel reliabilities. By improving likelihood of copies of the same variable node in a base graph being associated with similar channel reliabilities (e.g., by mapping them consistently to the MSB or LSB, for example), the SBPM scheme may improve a decoding threshold for a channel coding scheme, such as the QC-LDPC coding scheme described herein.

However, an SBPM scheme can result in performance degradation in some scenarios, such as high throughput scenarios (e.g., throughputs above 100 gigabits per second). For example, an SBPM scheme may result in degraded performance for transport block sizes near a switch point between two base graphs for an LDPC code. The switch point may be a threshold transport block size. For example, if a transport block has a size less than the threshold transport block size, a transmitter may encode the transport block using a first base graph. If the transport block has a size greater than the threshold transport block size, the transmitter may encode the transport block using a second base graph. For transport block sizes near the switch point, data encoded using the first base graph may experience worse performance (e.g., worse signal-to-noise ratio (SNR) performance) than data encoded using the second base graph (e.g., there may be a jump in performance near the switch point when switching to the second base graph). The jump or increase in performance may be caused by the SBPM scheme, rather than the LDPC encoding. Such jumps or increases in SNR performance may cause degraded performance for communications between the transmitter and the receiver because fluctuations in SNR conditions can cause degrade the decoding processing, increasing the risk of decoding errors, among other examples.

Additionally, or alternatively, the SBPM scheme may be associated with a higher error floor (e.g., a higher minimum block error rate supported). For example, SBPM may result in degraded performance in low error rate scenarios. In an LDPC encoding scheme that uses an accumulative (or degree-2) chain structure to reduce encoding complexity, degree-2 nodes may have an adverse impact on the error floor performance for the resulting LDPC codes. As another example, for a probabilistic shaping system that uses QC-LDPC codes, SBPM may be inapplicable because SBPM may result in parity bits being mapped to an LSB. For a probabilistic shaping system, a uniform distribution (e.g., a uniform probability distribution) of the parity bits should be preserved to preserve a zero mean property of the constellation. However, if parity bits are mapped to LSBs, the zero mean property of the constellation may be lost.

Various aspects relate generally to permutations for an LDPC code. Some aspects more specifically relate to an LDPC code that uses a permuted base graph to generate encoded information using the LDPC code (e.g., to generate an LDPC codeword). In some aspects, a network entity (e.g., a user equipment (UE) or a network node) may encode, based on a permutation pattern, first information to obtain encoded information. As used herein, “permutation pattern” refers to a sequence or order in which the columns of a base graph for an LDPC code are re-ordered or permuted, such as to optimize encoding and decoding processes, improve error correction performance, or achieve other desired communication characteristics. For example, the permutation pattern may indicate a permutation of one or more columns of a base graph for the LDPC code. A permutation pattern may also be referred to as a permutation, a column permutation, a column re-ordering, or an interleaving pattern, among other examples.

The permutation pattern may indicate a re-ordering of the columns of the base graph. The network entity may modulate the encoded information to map the encoded information to one or more constellation symbols. For example, the network entity may apply a depth-m block interleaver (e.g., similar to SBPM interleaving described herein) to map the encoded information to one or more constellation symbols (e.g., where depth-m refers to a block interleaver that using a matrix with m rows). The network entity may transmit a signal that indicates second information that is based on the one or more constellation symbols.

In some aspects, different permutation patterns may be configured for different transmission parameters. For example, different permutation patterns may be configured for different base graphs, different modulation orders, different modulation and coding schemes (MCSs), or different pairs of base graphs and MCSs, among other examples. In some aspects, the permutation pattern may indicate that one or more parity columns of the base graph are to be placed at a start of the base graph.

In some aspects, the permutation pattern may be associated with a probabilistic shaping system (e.g., a probabilistic amplitude shaping (PAS) system). For example, the network entity may perform, using the first information, a PAS operation to obtain shaped information. The network entity may encode, using a permuted order of the base graph, the shaped information to obtain the encoded information, where the permuted order enables the encoded information to maintain reliability levels for respective constellation symbols.

Particular aspects of the subject matter described in this disclosure can be implemented to realize one or more of the following potential advantages. In some examples, the described techniques can be used to improve the performance of an LDPC code. For example, by the network node encoding the information using the permuted base graph (e.g., using the permutation pattern for the base graph), the performance near a switch point between two base graphs for an LDPC code may be similar because the permutation pattern for a first base graph may improve the performance (e.g., the SNR threshold or the error floor) near the switching point at which the network entity may switch from using the first base graph to using a second base graph. This reduces the jump or increase in performance when switching base graphs for the LDPC code that may otherwise be caused by the SBPM scheme, as described herein.

In some aspects, the permutation pattern enables one or more columns of the base graph that include nodes that impact the error floor of the LDPC code to be mapped to an MSB. The MSB may be associated with improved error protection, thereby improving (e.g., lowering) the error floor of the LDPC code. For example, by the permutation pattern indicating one or more parity columns to be placed at the start of the base graph, this improves the likelihood that the network entity will map and transmit the parity bits (e.g., in the one or more parity columns) in MSB locations of constellation symbols after applying the depth-m block interleaver. In some examples, the parity bits may be associated with variable nodes that impact the error floor of the LDPC code. For example, by the network node encoding the information using the permuted base graph, the network node may encode and map bits that impact the performance of the LDPC code (e.g., certain degree-2 parity nodes in the base graph) to MSB locations in a constellation symbol, thereby improving the performance of the LDPC code. Additionally, by applying different permutation patterns for different modulation or coding parameters, the network entity can apply a permutation pattern that optimizes the reliability of the LDPC code for the modulation or coding parameters being applied for a given transmission or signal.

In some aspects, by the network entity applying a permutation pattern that is associated with a PAS operation, the network entity may match the reliability of uncoded shaped bits to the reliability of the columns of the base graph. This improves the likelihood of the probability distribution of parity bits being maintained during encoding and modulation. As a result, this may increase the likelihood that a zero mean property of a constellation can be maintained when applying the PAS operation and the depth-m block interleave operation described herein.

This disclosure may be readily utilized as a basis for modifying or designing other structures for carrying out the same purposes of the present disclosure. Such equivalent constructions do not depart from the scope of the appended claims. Characteristics of the example concepts disclosed herein, both their organization and method of operation, together with associated example advantages, are described in the following description and in connection with the accompanying figures. Each of the figures is provided for the purposes of illustration and description, and not as a definition of the limits of the claims.

While aspects are described in the present disclosure by illustration to some examples, those skilled in the art understand that such aspects may be implemented in many different arrangements and scenarios. Techniques described herein may be implemented using different platform types, devices, systems, shapes, sizes, or packaging arrangements. For example, some aspects may be implemented via integrated chip embodiments or other non-module-component based devices (e.g., end-user devices, vehicles, communication devices, computing devices, industrial equipment, retail/purchasing devices, medical devices, or artificial intelligence devices). Aspects may be implemented in chip-level components, modular components, non-modular components, non-chip-level components, device-level components, or system-level components. Devices incorporating described example aspects and example features may include additional example components and example features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, or summers). Aspects described herein may be practiced in a wide variety of devices, components, systems, distributed arrangements, or end-user devices of varying size, shape, and constitution.

5G New Radio (NR) may support enhanced mobile broadband (eMBB) access, Internet of Things (IoT) networks or reduced capability (RedCap) device deployments, ultra-reliable low-latency communication (URLLC) applications, or massive machine-type communication (mMTC), among other examples. To support these and other target verticals, a wireless communication system may be designed to implement a modularized functional infrastructure, a disaggregated and service-based network architecture, network function virtualization, network slicing, multi-access edge computing, millimeter wave (mm Wave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial or aerial platforms, among other examples.

The methods, operations, apparatuses, and techniques described herein may enable one or more of the foregoing technologies or new technologies or support one or more of the foregoing use cases or new use cases.

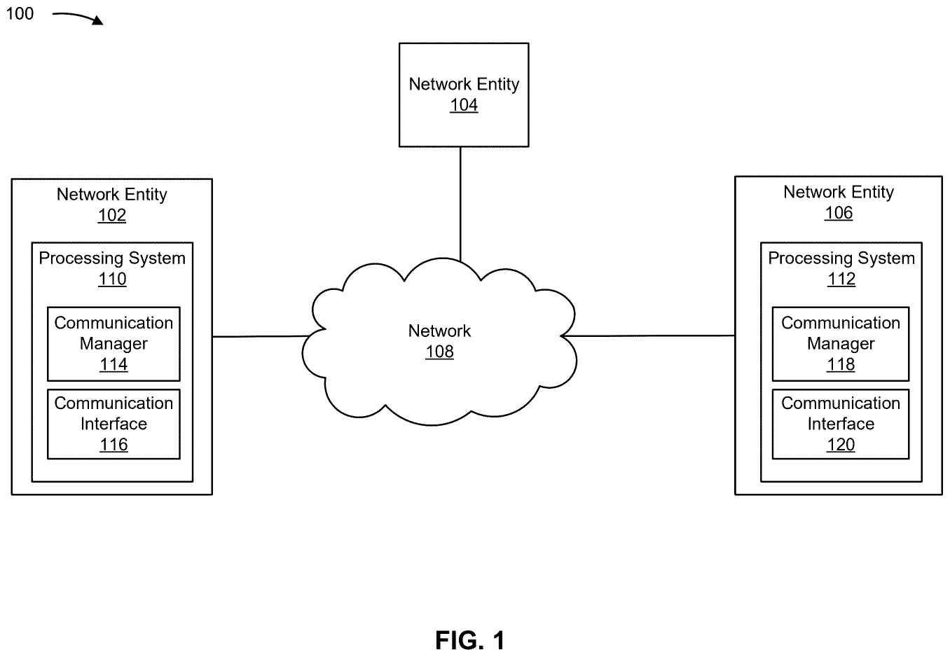

FIG. 1 is a diagram illustrating an example environment 100 in which apparatuses or methods described herein may be implemented. As shown in FIG. 1, the environment 100 may include a network entity 102, a network entity 104, and a network entity 106, that may communicate with one another via a network 108. The network entities 102, 104, and 106, may be dispersed throughout the network 108, and each network entity 102, 104, and 106 may be stationary or mobile. The network 108 may include wired communication connections, wireless communication connections, or a combination of wired and wireless communication connections.

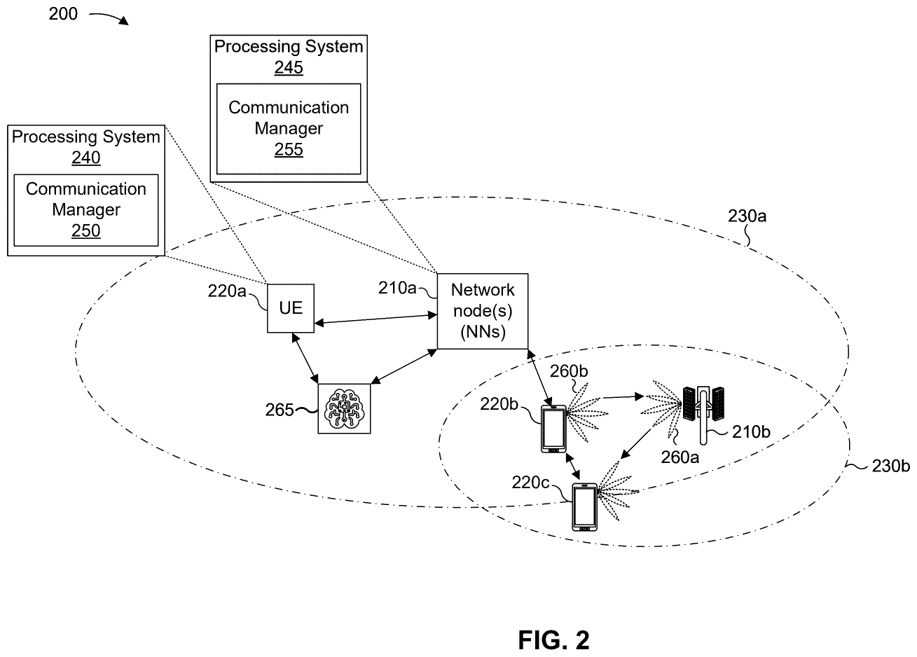

The network 108 may include, for example, a cellular network (e.g., a Long-Term Evolution (LTE) network, a CDMA network, a 4G network, a 5G network, a 6G network, or another type of next generation network), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, or a combination of these or other types of networks. The network 108 may include a wireless communication network 200, described in connection with FIG. 2.

As described herein, a network entity (which may alternatively be referred to as an entity, a node, a network node, or a wireless entity) may be, be similar to, include, or be included in (e.g., be a component of) a base station (e.g., any base station described herein, including a disaggregated base station), a UE (e.g., any UE described herein), a reduced capability (RedCap) device, an enhanced reduced capability (eRedCap) device, an ambient internet-of-things (IoT) device, an energy harvesting (EH)-capable device, a network controller, an apparatus, a device, a computing system, an integrated access and backhauling (IAB) node, a distributed unit (DU), a central unit (CU), a remote/radio unit (RU) (which may also be referred to as a remote radio unit (RRU)), or another processing entity configured to perform any of the techniques described herein. For example, a network entity may be a UE. As another example, a network entity may be a base station. As used herein, “network entity” may refer to an entity that is configured to operate in a network, such as the network 108. For example, a “network entity” is not limited to an entity that is currently located in or currently operating in the network. Rather, a network entity may be any entity that is capable of communicating or operating in the network. A network entity may include a network node 210 or a UE 220, described in more detail in connection with FIG. 2.

The adjectives “first,” “second,” “third,” and so on are used for contextual distinction between two or more of the modified noun in connection with a discussion and are not meant to be absolute modifiers that apply only to a certain respective entity throughout the entire document. For example, a network entity may be referred to as a “first network entity” in connection with one discussion and may be referred to as a “second network entity” in connection with another discussion, or vice versa. As an example, a first network entity may be configured to communicate with a second network entity or a third network entity. In one aspect of this example, the first network entity may be a UE, the second network entity may be a base station, and the third network entity may be a UE. In another aspect of this example, the first network entity may be a UE, the second network entity may be a base station, and the third network entity may be a base station. In yet other aspects of this example, the first, second, and third network entities may be different relative to these examples.

Similarly, reference to a UE, base station, apparatus, device, computing system, or the like may include disclosure of the UE, base station, apparatus, device, computing system, or the like being a network entity. For example, disclosure that a UE is configured to receive information from a base station also discloses that a first network entity is configured to receive information from a second network entity. Consistent with this disclosure, once a specific example is broadened in accordance with this disclosure (e.g., a UE is configured to receive information from a base station also discloses that a first network entity is configured to receive information from a second network entity), the broader example of the narrower example may be interpreted in the reverse, but in a broad open-ended way. In the example above where a UE is configured to receive information from a base station also discloses that a first network entity is configured to receive information from a second network entity, “first network entity” may refer to a first UE, a first base station, a first apparatus, a first device, a first computing system, a first set of one or more one or more components, a first processing entity, or the like configured to receive the information; and “second network entity” may refer to a second UE, a second base station, a second apparatus, a second device, a second computing system, a second set of one or more components, or a second processing entity, among other examples.

As described herein, communication of information (e.g., any information, signal, or the like) may be described in various aspects using different terminology. Disclosure of one communication term includes disclosure of other communication terms. For example, a first network entity may be described as being configured to transmit information to a second network entity. In this example and consistent with this disclosure, disclosure that the first network entity is configured to transmit information to the second network entity includes disclosure that the first network entity is configured to provide, send, output, communicate, or transmit information to the second network entity. Similarly, in this example and consistent with this disclosure, disclosure that the first network entity is configured to transmit information to the second network entity includes disclosure that the second network entity is configured to receive, obtain, or decode the information that is provided, sent, output, communicated, or transmitted by the first network entity.

As shown, the network entity 102 may include a processing system 110. Similarly, the network entity 106 may include a processing system 112. A processing system may include one or more components (or subcomponents), such as one or more components described herein. For example, a respective component of the one or more components may be, be similar to, include, or be included in at least one memory, at least one communication interface, or at least one processor. For example, a processing system may include one or more components. In such an example, the one or more components may include a first component, a second component, and a third component. In this example, the first component may be coupled to a second component and a third component. In this example, the first component may be at least one processor, the second component may be a communication interface, and the third component may be at least one memory. A processing system may generally be a system including one or more components that may perform one or more functions, such as any function or combination of functions described herein. For example, one or more components may receive input information (e.g., any information that is an input, such as a signal, any digital information, or any other information), one or more components may process the input information to generate output information (e.g., any information that is an output, such as a signal or any other information), one or more components may perform any function as described herein, or any combination thereof. A processing system (which may include the processing system 110 and the processing system 112) is described in more detail in connection with FIG. 2, such as in connection with processing system 240 and processing system 245.

As described herein, an “input” and “input information” may be used interchangeably. Similarly, as described herein, an “output” and “output information” may be used interchangeably. Any information generated by any component may be provided to one or more other systems or components of, for example, a network entity described herein. For example, a processing system may include a first component configured to receive or obtain information, a second component configured to process the information to generate output information, or a third component configured to provide the output information to other systems or components. In this example, the first component may be a communication interface (e.g., a first communication interface), the second component may be at least one processor (e.g., that is coupled to the communication interface or at least one memory), and the third component may be a communication interface (e.g., the first communication interface or a second communication interface). For example, a processing system may include at least one memory, at least one communication interface, or at least one processor, where the at least one processor may, for example, be coupled to the at least one memory and the at least one communication interface.

A processing system of a network entity described herein may interface with one or more other components of the network entity, may process information received from one or more other components (such as input information), or may output information to one or more other components. For example, a processing system may include a first component configured to interface with one or more other components of the network entity to receive or obtain information, a second component configured to process the information to generate one or more outputs, or a third component configured to output the one or more outputs to one or more other components. In this example, the first component may be a communication interface (e.g., a first communication interface), the second component may be at least one processor (e.g., that is coupled to the communication interface or at least one memory), and the third component may be a communication interface (e.g., the first communication interface or a second communication interface). For example, a chip or modem of the network entity may include a processing system. The processing system may include a first communication interface to receive or obtain information, and a second communication interface to output, transmit, or provide information. In some examples, the first communication interface may be an interface configured to receive input information, and the information may be provided to the processing system. In some examples, the second system interface may be configured to transmit information output from the chip or modem. The second communication interface may also obtain or receive input information, and the first communication interface may also output, transmit, or provide information.

For example, as shown in FIG. 1, the processing system 110 may include a (e.g., one or more) communication manager 114 and one or more communication interfaces 116. The communication manager 114 may be configured to perform one or more communication tasks as described herein. In some aspects, the communication manager 114 may direct the communication interface 120 or the processing system 110 to perform one or more communication tasks as described herein. Similarly, the processing system 112 may include a (e.g., one or more) communication manager 118 and one or more communication interfaces 120. The communication manager 118 may be configured to perform one or more communication tasks as described herein. In some aspects, the processing system 112 or the communication manager 118 may direct the communication interface 120 to perform one or more communication tasks as described herein. Although depicted, for clarity of description, with reference only to the network entities 102 and 104, any one or more of the network entities 102, 104, and 106 also may include a communication manager and a communication interface.

As used herein, “communication interface” refers to an interface that enables communication (e.g., wireless communication, wired communication, or a combination thereof) between a first network entity and a second network entity. A communication interface may include electronic circuitry that enables a network entity to transmit, receive, or otherwise perform the communication. A communication interface may be, be similar to, include, or be included in one or more components that are configured to enable communication between the first network entity and the second network entity. For example, a communication interface may include a transmission component, a reception component, or a transceiver, among other examples. For example, a communication interface may include one or more transceivers, one or more receivers, or one or more transmitters configured to communicate with other devices, such as via a wired connection, a wireless connection, or a combination of wired and wireless connections. In some examples, a communication interface may include one or more RF components, an RF front end, one or more antennas, one or more transmit or receive processors, a demodulation component, or a modulation component, among other examples.

A communication interface may include a transmission component or a reception component. For example, a communication interface may include a transceiver or one or more separate receivers or transmitters that enable a network entity to communicate with other devices, such as via a wired connection, a wireless connection, or a combination of wired and wireless connections. In some examples, a communication interface may include one or more radio frequency reflective elements or one or more radio frequency refractive elements. The communication interface may enable the network entity to receive information from another apparatus or provide information to another apparatus. In some examples, the communication interface may include an Ethernet interface, an optical interface, a coaxial interface, an infrared interface, an RF interface, a universal serial bus (USB) interface, a Wi-Fi interface, a cellular network interface, a wireless modem, an inter-integrated circuit (I²C), or a serial peripheral interface (SPI), among other examples.

As described herein, a network entity (e.g., the network entity 102 or the network entity 106) may be configured to perform one or more operations. Reference to a network entity being configured to perform one or more operations may refer to a processing system of the network entity being configured to perform the one or more operations or the processing system being configured to cause one or more components of the network entity to perform the one or more operations. For example, reference to the processing system being configured to perform one or more operations may refer to one or more components (or subcomponents) of the processing system performing the one or more operations. For example, the one or more components of the processing system may include at least one memory, at least one processor, or at least one communication interface, among other examples, that are configured to perform one or more (or all) of the one or more operations, or any combination thereof. Where reference is made to the network entity or the processing system being configured to perform operations, the network entity or the processing system may be configured to cause one component to perform all operations, or to cause more than one component to collectively perform the operations. When the network entity or the processing system is configured to cause more than one component to collectively perform the operations, each operation need not be performed by each of those components (e.g., different operations may be performed by different components) or each operation need not be performed in whole by only one component (e.g., different components may perform different sub-functions of an operation).

As described in more detail elsewhere herein, the network entity 102 may (e.g., the processing system 110 may, or the processing system 110 may cause the communication manager 114 or the communication interface 116 to) encode first information to obtain encoded information, wherein the permutation pattern is associated with columns of a base graph for a low-density parity check code; modulate the encoded information to map the encoded information to one or more constellation symbols; and transmit a signal that indicates second information that is based on the one or more constellation symbols. Additionally, or alternatively, the network entity 102 or the processing system 110 may perform one or more other operations described herein.

As described in more detail elsewhere herein, the network entity 106 may (e.g., the processing system 112 may, or the processing system 112 may cause the communication manager 118 or the communication interface 120 to) receive a signal that indicates first information associated with one or more constellation symbols; demodulate the first information to obtain encoded information; and decode the encoded information to obtain second information, wherein the permutation pattern is associated with columns of a base graph for a low-density parity check code. Additionally, or alternatively, the network entity 106 or the processing system 112 may perform one or more other operations described herein.

The number and arrangement of entities shown in FIG. 1 are provided as one or more examples. In practice, there may be additional network entities or networks, fewer network entities or networks, different network entities or networks, or differently arranged network entities or networks than those shown in FIG. 1. Furthermore, the network entity 102, 104, and 106 may be implemented using a single apparatus or multiple apparatuses.

FIG. 2 is a diagram illustrating an example of a wireless communication network 200. The wireless communication network 200 may be or may include elements of a 5G network or a 6G network, among other examples. The wireless communication network 200 may include multiple network nodes 210. For example, in FIG. 2, the wireless communication network 200 includes multiple network nodes 210, including a network node 210a and a network node 210b (each of which also may be referred to herein simply as a “network node 210”). The network nodes 210 may support communications with multiple UEs 220. For example, in FIG. 2, the network nodes 210 support communication with a UE 220a, a UE 220b, and a UE 220c (each of which also may be referred to herein simply as a “UE 220”). In some examples, a UE 220 also may communicate with other UEs 220 and a network node 210 also may communicate with a core network and with other network nodes 210. A network node 210 and a UE 220 may be examples of a network entity described herein, such as the network entity 102, the network entity 104, or the network entity 106.

The network nodes 210 and the UEs 220 of the wireless communication network 200 communicate using the electromagnetic spectrum, which may be subdivided into various licensed or unlicensed operating bands, frequency ranges, component carriers, or channels that define associated frequencies available for communications. In some examples, each of the network nodes 210 and the UEs 220 may communicate using one or multiple component carriers in one or more operating bands or ranges. Typically, various operating bands are defined as frequency range designations FR1 (410 MHz through 7.125 GHz), FR2 (24.25 GHz through 52.6 GHz), FR3 (7.125 GHz through 24.25 GHZ), FR4a or FR4-1 (52.6 GHz through 71 GHz), FR4 (52.6 GHz through 114.25 GHZ), and FR5 (114.25 GHz through 300 GHz). Although a portion of FR1 is greater than 6 GHz, FR1 is often referred to (interchangeably) as a “sub-6 GHz” band in some documents and articles. Similarly, FR2 is often referred to (interchangeably) as a “millimeter wave” band in some documents and articles.

A network node 210 or a UE 220 may include one or more devices, components, or systems that enable communication with other devices, components, or systems of the wireless communication network 200. For example, a UE 220 and a network node 210 may each include one or more chips, system-on-chips (SoCs), chipsets, packages, or devices that individually or collectively constitute or comprise a processing system. As shown in FIG. 2, each UE 220 includes a processing system 240 and each network node 210 includes a processing system 245. A processing system (for example, the processing system 240 or the processing system 245) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 240 and the processing system 245 may each include memory circuitry in the form of one or multiple memory devices, memory blocks, memory elements, or other discrete gate or transistor logic or circuitry, each of which may include or implement tangible storage media, such as random-access memory, or read-only memory, or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors. One or more of the memories may individually or collectively store processor-executable code or instructions (such as software) (for example, which may be referred to as “one or more code-storing memories” or “code-storing memory circuitry”). For example, “code-storing memory” or “code-storing memory circuitry” refers to memory (or memory circuitry) that is configured to store processor-executable code or instructions. The processor-executable code or instructions, when executed by one or more of the processors, may configure one or more of the processors (or processing circuitry) to perform various functions or operations described herein. Additionally, or alternatively, in some examples, one or more of the processors may be configured to perform various functions or operations described herein without requiring configuration by software. Software shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 240 and the processing system 245 may each include or be coupled with one or more modems (such as a cellular (for example, a 5G or 6G compliant) modem). In some examples, one or more processors of the processing system 240 or the processing system 245 may include or implement one or more of the modems. The processing system 240 and the processing system 245 also may include or be coupled with multiple radios (collectively “the radio”), multiple RF chains, or multiple transceivers, each of which may in turn be coupled with one or more of multiple antennas. In some examples, one or more processors of the processing system 240 or the processing system 245 may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by the processing system 240 or by the processing system 245).

A network node 210 and a UE 220 may each include one or multiple antennas or antenna arrays. Typical network nodes 210 and UEs 220 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device, such as the network node 210 and the UE 220.

A network node 210 may be, may include, or also may be referred to as an NR network node, a 5G network node, a 6G network node, a Node B, a gNB, an access point (AP), a transmission reception point (TRP), a network entity, a network element, a network equipment, or another type of device, component, or system included in a radio access network (RAN). In various deployments, a network node 210 may be implemented as a single physical node (for example, a single physical structure) or may be implemented as two or more physical nodes (for example, two or more distinct physical structures). For example, a network node 210 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 210 may be an aggregated network node having an aggregated architecture, meaning that the network node 210 may implement a full radio protocol stack that is physically and logically integrated within a single physical structure in the wireless communication network 200. For example, an aggregated network node 210 may include a single standalone base station or a single TRP that operates with a full radio protocol stack to enable or facilitate communication between a UE 220 and a core network of the wireless communication network 200.

Alternatively, and as also shown, a network node 210 may be a disaggregated network node 210 (sometimes referred to as a disaggregated base station), having a disaggregated architecture, meaning that the network node 210 may operate with a radio protocol stack that is physically distributed or logically distributed among two or more nodes in the same geographic location or in different geographic locations. In some deployments, disaggregated network nodes 210 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The disaggregated network nodes 210 of the wireless communication network 200 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A DU may host one or more of a radio link control (RLC) layer, a medium access control (MAC) layer, or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 220. In some examples, a single network node 210 may include a combination of one or more CUs, one or more DUs, or one or more RUs. In some examples, a CU, a DU, or an RU may be implemented as a virtual unit, such as a virtual central unit (VCU), a virtual distributed unit (VDU), or a virtual radio unit (VRU), among other examples, which may be implemented as a virtual network function, such as in a cloud deployment.

In some examples, the wireless communication network 200 may be a heterogeneous network that includes network nodes 210 of various types. Different types of network nodes 210 may generally operate on the same or different operating bands, transmit at different power levels, or serve different coverage areas, each of which may be referred to as or associated with a particular cell 230 (for example, a cell 230a and a cell 230b).

The UEs 220 may be physically dispersed throughout the coverage area of the wireless communication network 200, and each UE 220 may be stationary or mobile. A UE 220 may be, may include, or also may be referred to as an access terminal, a mobile station, a client device, or a subscriber unit. A UE 220 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), an artificially intelligent robot or other device implementing artificial intelligence, a UE function of a network node, or any other suitable device or function that may communicate in the wireless communication network 200.

Some UEs 220 may be classified according to different categories in association with different complexities or different capabilities. UEs 220 in a first category may be associated with relatively low complexity or cost such as NB-IoT devices or eMTC UEs. UEs 220 in a second category may include higher complexity or cost devices, such as mission-critical IoT devices, baseline UEs, high-tier UEs, advanced UEs, full-capability UEs, or premium UEs that are capable of URLLC, eMBB, or precise positioning in the wireless communication network 200. A third category of UEs 220 may have mid-tier complexity or capabilities (for example, capabilities between that of the UEs 220 of the first category and the UEs 220 of the second category). A UE 220 of the third category may be referred to as a reduced capability UE (“RedCap UE”), a mid-tier UE, an NR-Light UE, or an NR-Lite UE, among other examples.

In some examples, a network node 210 may be, may include, or may operate as an RU, a TRP, or a base station that communicates with one or more UEs 220 via a radio access link (which may be referred to as a “Uu” link). The radio access link may include a downlink and an uplink. “Downlink” (or “DL”) refers to a communication direction from a network node 210 to a UE 220, and “uplink” (or “UL”) refers to a communication direction from a UE 220 to a network node 210. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 220 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 210 transmitting a downlink control information (DCI) configuration to the one or more UEs 220) or reconfigured (for example, in real-time or near-real-time) according to changing network conditions in the wireless communication network 200 or specific requirements of one or more UEs 220. An active BWP defines the operating bandwidth of the UE 220 within the operating bandwidth of the serving cell.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PBCH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications or downlink data channel communications. A downlink control channel may be specifically used to transmit DCI from a network node 210 to a UE 220. DCI generally contains the information the UE 220 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 220) from a network node 210 to a UE 220. Downlink control channels may include physical downlink control channels (PDCCHs), and downlink data channels may include physical downlink shared channels (PDSCHs). Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more transport blocks (TBs) of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. Uplink reference signals may be transmitted in addition to, or multiplexed with, uplink control channel communications or uplink data channel communications. An uplink control channel may be specifically used to transmit uplink control information (UCI) from a UE 220 to a network node 210. An uplink data channel may be used to transmit uplink data (for example, user data associated with a UE 220) from a UE 220 to a network node 210. Uplink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ acknowledgement (ACK) indication or a HARQ negative acknowledgement (NACK) indication), uplink power control information (for example, an uplink TPC parameter), or CSI, among other examples. CSI can include a channel quality indicator (CQI) (indicative of downlink channel conditions to facilitate selection of transmission parameters, such as an MCS, by a network node 210), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 210 to a UE 220, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 210 or UE 220 over a wireless communication channel. In some examples, the network node 210 or the UE 220 (for example, using the processing system 245 or the processing system 240, respectively) may select an MCS (for example, an order of quadrature amplitude modulation (QAM), such as 64-QAM, 128-QAM, or 256-QAM, among other examples) for a downlink signal or an uplink signal. For example, the network node 210 may select an MCS for a downlink signal in accordance with UCI received from the UE 220 or may transmit, to the UE 220, an indication of an MCS to be applied for an uplink signal.

A network node 210 or a UE 220 (such as by using the processing system 245 or the processing system 240, respectively, or one or more coupled modems) may perform signal processing on the information (such as filtering, amplification, modulation, digital-to-analog conversion, an IFFT operation, multiplexing, interleaving, mapping, or encoding, among other examples) to generate a processed signal in accordance with the selected MCS. In some examples, the network node 210 or the UE 220 (for example, using the processing system 245 or the processing system 240, respectively, or one or more coupled encoders or modems) may perform a channel coding operation or a forward error correction (FEC) operation to control errors in transmitted information. For example, the network node 210 or the UE 220 may perform an encoding operation to generate encoded information (such as by selectively introducing redundancy into the information, typically using an error correction code (ECC), such as a polar code or an LDPC code). The network node 210 or the UE 220 (for example, using the processing system 245 or one or more modems) may further perform spatial processing (for example, precoding) on the encoded information to generate one or more processed or precoded signals for downlink or uplink transmission, respectively. In some examples, the network node 210a or the UE 220a may perform codebook-based precoding or non-codebook-based precoding. Codebook-based precoding may involve selecting a precoder (for example, a precoding matrix) using a codebook. For example, the network node 210a may provide precoding information indicating which precoder, defined by the codebook, is to be used by the UE 220a. Non-codebook-based precoding may involve selecting or deriving a precoder based on, or otherwise associated with, one or more downlink or uplink signal measurements. The network node 210a or the UE 220a may transmit the processed downlink or uplink signals, respectively, via one or more antennas.

The network node 210a or the UE 220a may receive uplink signals or downlink signals, respectively, via one or more antennas. The network node 210a or the UE 220a (for example, using the processing system 245 or the processing system 240, respectively, or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, or decoding, among other examples), to map the received signal(s) to a sequence of binary bits (for example, received information) that estimates the information transmitted by the network node 210 or the UE 220 via the downlink or uplink signals. The network node 210a or the UE 220a (for example, using the processing system 245 or the processing system 240, respectively, or a coupled decoder or one or more modems) may decode the received information (such as by using an ECC, a decoding operation, or an FEC operation) to detect errors or correct bit errors in the received information to generate decoded information. The decoded information may estimate the information transmitted via the downlink or uplink signals.

In some examples, a UE 220 and a network node 210 may perform MIMO communication. MIMO communication generally refers to transmitting or receiving multiple signals (such as multiple layers or multiple data streams) simultaneously over the same time and frequency resources. A network node 210 or a UE 220 may communicate using single-user MIMO or multi-user MIMO (MU-MIMO), the latter of which being used by a network node 210 to simultaneously transmit signals to multiple UEs 220. MIMO techniques may involve spatial multiplexing (multi-layer transmission) or beamforming. To implement beamforming, the amplitudes or phases of signals transmitted via antenna elements may be modulated and shifted relative to each other (such as by manipulating a phase shift, a phase offset, or an amplitude) to generate one or more beams. For example, a network node 210 may generate one or more beams 260a, and a UE 220 may generate one or more beams 260b. The term “beam” may refer to a directional transmission of a wireless signal toward a receiving device or otherwise in a desired direction, a directional reception of a wireless signal from a transmitting device or otherwise in a desired direction, a direction associated with such a directional transmission or directional reception, a set of directional resources associated with a signal transmission or signal reception (for example, an angle of arrival, a horizontal direction, or a vertical direction), or a set of parameters or resources associated with one or more aspects of a directional signal, among other examples.

In some examples, a network node 210 or a UE 220 may implement massive MIMO, which may be associated with an increased (for example, “massive”) quantity of antennas at the network node 210 or at the UE 220, such as in a network implementing mmWave technology, which enables more precise beamforming or reduced interference. In some examples, the wireless communication network 200 may implement multi-TRP (mTRP) operation (including redundant transmission or reception on multiple TRPs) or non-coherent joint transmission (NC-JT).

The network node 210 and the UE 220 may establish a communication link or beam pair, and otherwise increase reliability, throughput, signal strength, or other signal properties for MIMO communications, by performing beam management operations, such as an initial beam acquisition operation, a beam refinement operation, or a beam recovery operation. For example, an initial beam acquisition operation may involve the network node 210 transmitting signals (for example, SSBs or other signals) via respective beams (for example, of the beams 260 of the network node 210) and the UE 220 receiving and measuring the signal(s) via respective beams of multiple beams (for example, from the beams 260 of the UE 220) to identify a best beam (or beam pair) for communication between the UE 220 and the network node 210. A beam refinement operation may involve a first device (for example, the UE 220 or the network node 210) transmitting signal(s) via a subset of beams (for example, identified based on, or otherwise associated with, measurements reported as part of one or more other beam management operations). A second device (for example, the network node 210 or the UE 220) may receive the signal(s) via a single beam (for example, to identify the best beam for communication from the subset of beams). The beam(s) may be identified or defined via one or more spatial parameters, such as a transmission configuration indicator (TCI) state or a quasi co-location (QCL) parameter, among other examples.

Some aspects and techniques as described herein may be implemented, at least in part, using an artificial intelligence (AI) program (for example, referred to herein as an “AI/ML model”), such as a program that includes a machine learning (ML) model or an artificial neural network (ANN) model. The AI/ML model may be deployed at one or more devices 265 (for example, one or more network nodes 210, one or more UEs 220, one or more servers, or one or more components of a cloud computing network, among other examples). For example, in a deployment in which AI/ML functionality is performed independently at a device 265, sometimes referred to as “overlay AI/ML,” the AI/ML model (or an instance or portion of the AI/ML model) may be deployed at a UE 220 (for example, by the processing system 240), a network node 210 (for example, by the processing system 245), one or more servers, or one or more components of a cloud computing network, among other examples. Additionally, or alternatively, in a deployment where AI/ML functionality is coordinated between different devices 265, sometimes referred to as “coordinated AI/ML,” or performed at all device and network layers, sometimes referred to as “native AI/ML,” the AI/ML model (or an instance of the AI/ML model) may be deployed at multiple devices 265 (for example, a first portion of the AI/ML model may be deployed at a UE 220 and a second portion of the AI/ML model may be deployed at a network node 210). In other examples of coordinated AI/ML or native AI/ML, a first AI/ML model may be deployed at a UE 220 and a second AI/ML model may be deployed at a network node 210. The AI/ML model(s) may be configured to enhance various aspects of the wireless communication network 200 (for example, to increase privacy, reliability, or efficient use of network bandwidth, or to reduce latency, among other examples). For example, the AI/ML model(s) may be trained to identify patterns or relationships in data corresponding to the wireless communication network 200, a device, or an air interface, among other examples. The AI/ML model(s) may support operational decisions relating to one or more aspects associated with wireless communications devices, networks, or services.

Accordingly, in some examples, the AI/ML model(s) may enable AI-as-a-Service (for example, an end-to-end AI/ML service via a user plane) for use cases, such as a self-organizing network (SON), minimization of drive test (MDT), quality of experience (QoE), positioning, sensing, predictive mobility, or traffic prediction, among other examples. In some examples, AI-as-a-Service use cases may include measurement collection reporting by a UE 220, device selection criteria (for example, according to a geographical area where measurements are to be collected or UE capabilities to be used to collected measurements), or reporting configurations (for example, reporting parameters such as location, time, or sensor information, among other examples). Additionally, or alternatively, the AI/ML model(s) may enable AI/ML procedures (for example, RAN-triggered service establishment, configuration, inferencing using UE-side or network-side models, performance monitoring or management, or capability signaling, among other examples). Additionally, or alternatively, the AI/ML model(s) may enable RAN-based AI/ML services via one or more application program interfaces (APIs) or management interfaces for use cases, such as beam management, radio resource monitoring (RRM) relaxation, mobility prediction, load prediction, network energy savings, or coverage and capacity improvements, among other examples.

In some aspects, a network entity (e.g., the UE 220) may include a communication manager 250. As described in more detail elsewhere herein, the communication manager 250 may encode first information to obtain encoded information, wherein the permutation pattern is associated with columns of a base graph for a low-density parity check code; modulate the encoded information to map the encoded information to one or more constellation symbols; and transmit a signal that indicates second information that is based on the one or more constellation symbols. Additionally, or alternatively, the communication manager 250 may receive a signal that indicates first information associated with one or more constellation symbols; demodulate the first information to obtain encoded information; and decode the encoded information to obtain second information, wherein the permutation pattern is associated with columns of a base graph for a low-density parity check code. Additionally, or alternatively, the communication manager 250 may perform one or more other operations described herein.

In some aspects, a network entity (e.g., the network node 210) may include a communication manager 255. As described in more detail elsewhere herein, the communication manager 255 may receive a signal that indicates first information associated with one or more constellation symbols; demodulate the first information to obtain encoded information; and decode the encoded information to obtain second information, wherein the permutation pattern is associated with columns of a base graph for a low-density parity check code. Additionally, or alternatively, the communication manager 255 may encode first information to obtain encoded information, wherein the permutation pattern is associated with columns of a base graph for a low-density parity check code; modulate the encoded information to map the encoded information to one or more constellation symbols; and transmit a signal that indicates second information that is based on the one or more constellation symbols. Additionally, or alternatively, the communication manager 250 may receive a signal that indicates first information associated with one or more constellation symbols; demodulate the first information to obtain encoded information; and decode the encoded information to obtain second information, wherein the permutation pattern is associated with columns of a base graph for a low-density parity check code. Additionally, or alternatively, the communication manager 255 may perform one or more other operations described herein.

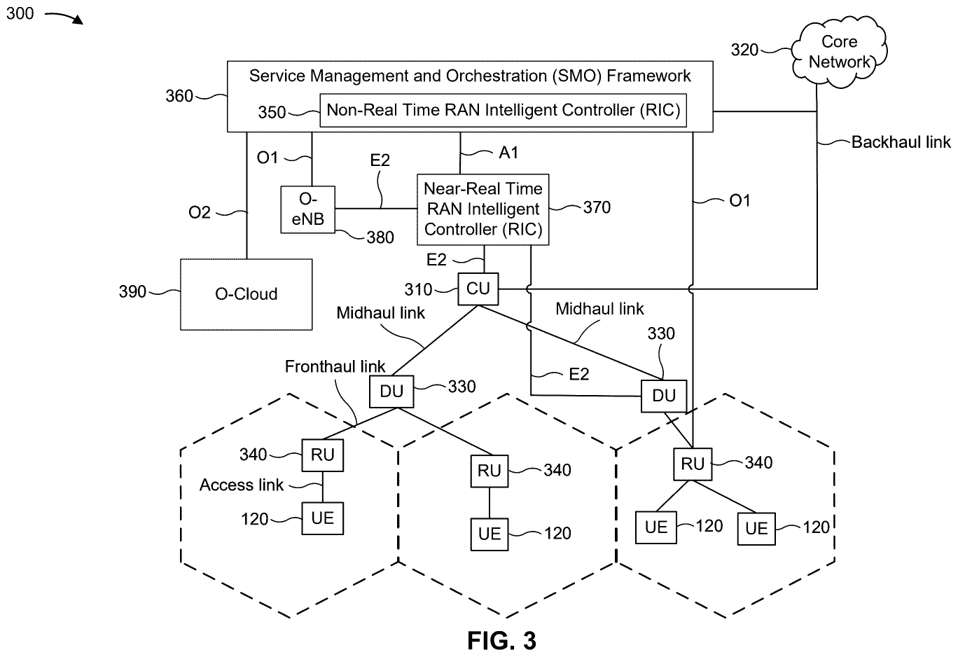

FIG. 3 is a diagram illustrating an example disaggregated network node architecture 300. One or more components of the example disaggregated network node architecture 300 may be, may include, or may be included in one or more network nodes (such one or more network nodes 210). The disaggregated network node architecture 300 may include a CU 310 that can communicate directly with a core network 320 via a backhaul link, or that can communicate indirectly with the core network 320 via one or more disaggregated control units, such as a non-real-time (Non-RT) RAN intelligent controller (RIC) 350 associated with a Service Management and Orchestration (SMO) Framework 360 or a near-real-time (Near-RT) RIC 370 (for example, via an E2 link). The CU 310 may communicate with one or more DUs 330 via respective midhaul links, such as via F1 interfaces. Each of the DUs 330 may communicate with one or more RUs 340 via respective fronthaul links. Each of the RUs 340 may communicate with one or more UEs 220 via respective RF access links. In some deployments, a UE 220 may be simultaneously served by multiple RUs 340.

Each of the components of the disaggregated network node architecture 300, including the CUs 310, the DUs 330, the RUs 340, the Near-RT RICs 370, the Non-RT RICs 350, and the SMO Framework 360, may include one or more interfaces or may be coupled with one or more interfaces for receiving or transmitting signals, such as data or information, via a wired or wireless transmission medium.

In some aspects, the CU 310 may be logically split into one or more CU user plane (CU-UP) units and one or more CU control plane (CU-CP) units. A CU-UP unit may communicate bidirectionally with a CU-CP unit via an interface, such as the E1 interface when implemented in an O-RAN configuration. The CU 310 may be deployed to communicate with one or more DUs 330, as necessary, for network control and signaling. Each DU 330 may correspond to a logical unit that includes one or more base station functions to control the operation of one or more RUs 340. For example, a DU 330 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 330, or for communicating signals with the control functions hosted by the CU 310. Each RU 340 may implement lower layer functionality. In some aspects, real-time and non-real-time aspects of control and user plane communication with the RU(s) 340 may be controlled by the corresponding DU 330.

The SMO Framework 360 may support RAN deployment and provisioning of non-virtualized and virtualized network elements. For non-virtualized network elements, the SMO Framework 360 may support the deployment of dedicated physical resources for RAN coverage requirements, which may be managed via an operations and maintenance interface, such as an O1 interface. For virtualized network elements, the SMO Framework 360 may interact with a cloud computing platform (such as an open cloud (O-Cloud) platform 390) to perform network element life cycle management (such as to instantiate virtualized network elements) via a cloud computing platform interface, such as an O2 interface. A virtualized network element may include, but is not limited to, a CU 310, a DU 330, an RU 340, a non-RT RIC 350, or a Near-RT RIC 370. In some aspects, the SMO Framework 360 may communicate with a hardware aspect of a 4G RAN, a 5G NR RAN, or a 6G RAN, such as an open eNB (O-eNB) 380, via an O1 interface. Additionally or alternatively, the SMO Framework 360 may communicate directly with each of one or more RUs 340 via a respective O1 interface. In some deployments, this configuration can enable each DU 330 and the CU 310 to be implemented in a cloud-based RAN architecture, such as a vRAN architecture.

The Non-RT RIC 350 may include or may implement a logical function that enables non-real-time control and optimization of RAN elements and resources, AI/ML workflows including model training and updates, or policy-based guidance of applications or features in the Near-RT RIC 370. The Non-RT RIC 350 may be coupled to or may communicate with (such as via an A1 interface) the Near-RT RIC 370. The Near-RT RIC 370 may include or may implement a logical function that enables near-real-time control and optimization of RAN elements and resources via data collection and actions via an interface (such as via an E2 interface) connecting one or more CUs 310, one or more DUs 330, or an O-eNB 380 with the Near-RT RIC 370.

In some aspects, to generate AI/ML models to be deployed in the Near-RT RIC 370, the Non-RT RIC 350 may receive parameters or external enrichment information from external servers. Such information may be utilized by the Near-RT RIC 370 and may be received at the SMO Framework 360 or the Non-RT RIC 350 from non-network data sources or from network functions. In some examples, the Non-RT RIC 350 or the Near-RT RIC 370 may tune RAN behavior or performance. For example, the Non-RT RIC 350 may monitor long-term trends and patterns for performance and may employ AI/ML models to perform corrective actions via the SMO Framework 360 (such as reconfiguration via an O1 interface) or via creation of RAN management policies (such as A1 interface policies).

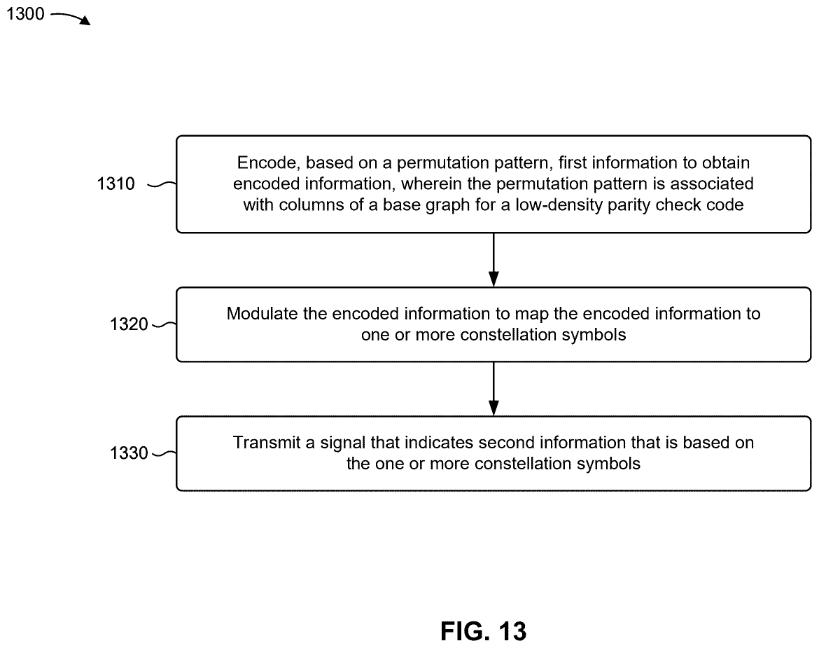

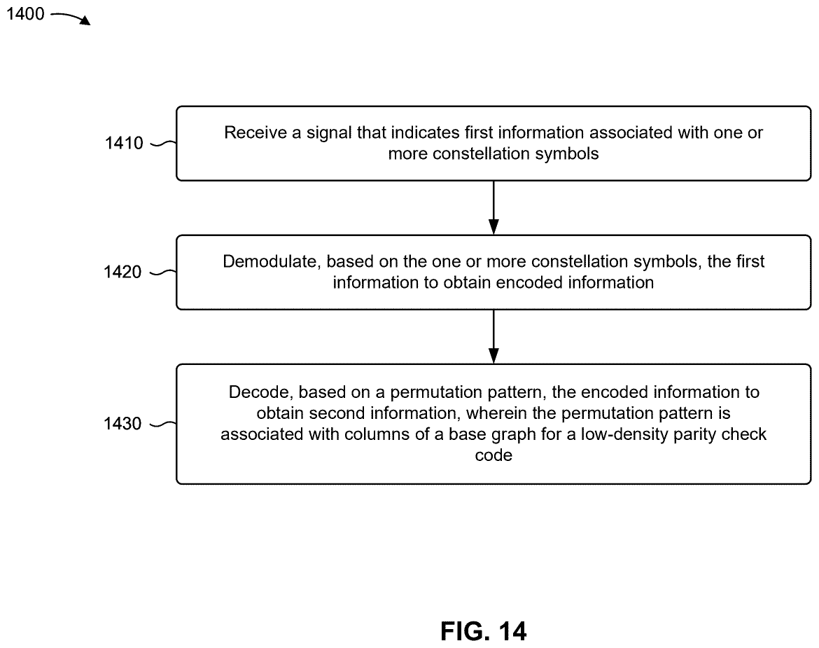

The network entity 102, the processing system 110 of the network entity 102, the network entity 106, the processing system 112 of the network entity 106, the network node 210, the processing system 245 of the network node 210, the UE 220, the processing system 240 of the UE 220, the CU 310, the DU 330, the RU 340, or any other component(s) of FIGS. 1-3 may implement one or more techniques or perform one or more operations associated with permutations for a low-density parity check code, as described in more detail elsewhere herein. For example, the processing system 110 of the network entity 102, the processing system 112 of the network entity 106, the processing system 245 of the network node 210, the processing system 240 of the UE 220, the CU 310, the DU 330, or the RU 340 may perform or direct operations of, for example, process 1300 of FIG. 13, process 1400 of FIG. 14, or other processes as described herein (alone or in conjunction with one or more other processors). Memory of the network node 210 may store data and program code (or instructions) for the network node 210, the CU 310, the DU 330, or the RU 340. In some examples, the memory of the network node 210 may store data relating to a UE 220, such as RRC state information or a UE context. Memory of a UE 220 may store data and program code (or instructions) for the UE 220, such as context information. In some examples, the memory of the UE 220 or the memory of the network node 210 may include a non-transitory computer-readable medium storing a set of instructions for wireless communication. For example, the set of instructions, when executed by one or more processors (for example, of the processing system 110, the processing system 112, the processing system 245, or the processing system 240) of the network entity 102, the network entity 106, the network node 210, the UE 220, the CU 310, the DU 330, or the RU 340, may cause the one or more processors to perform process 1300 of FIG. 13, process 1400 of FIG. 14, or other processes as described herein. In some examples, executing instructions may include running the instructions, converting the instructions, compiling the instructions, or interpreting the instructions, among other examples.

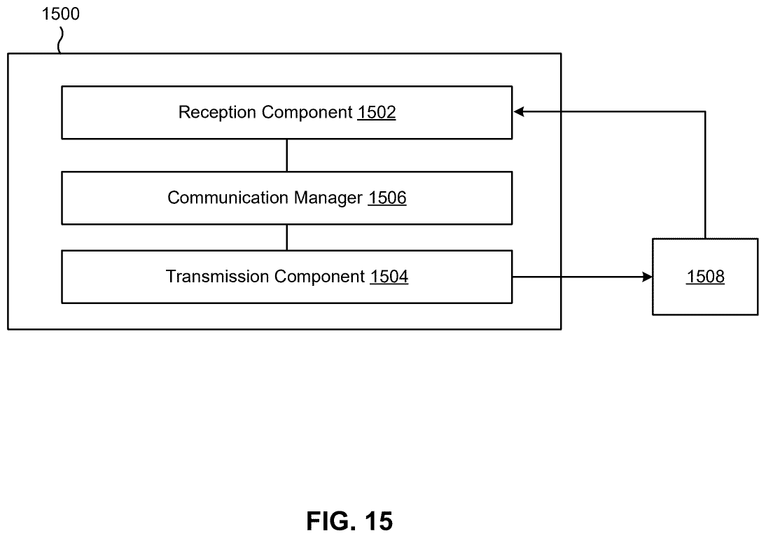

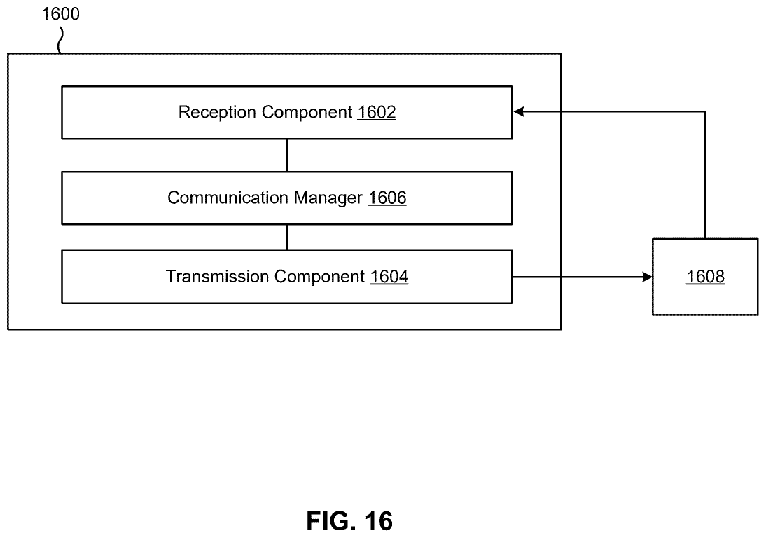

In some aspects, a network entity (e.g., a transmitter, such as a UE 220 or a network node 210) includes means for encoding, based on a permutation pattern, first information to obtain encoded information, wherein the permutation pattern is associated with columns of a base graph for a low-density parity check code; means for modulating the encoded information to map the encoded information to one or more constellation symbols; or means for transmitting a signal that indicates second information that is based on the one or more constellation symbols. In some aspects, the means for the first network entity to perform operations described herein may include, for example, one or more of communication manager 250, processing system 240, processing system 110, communication manager 114, communication interface 116, processing system 112, communication manager 118, communication interface 120, a radio, one or more RF chains, one or more transceivers, one or more antennas, one or more modems, a reception component (for example, reception component 1502 depicted and described in connection with FIG. 15) or a transmission component (for example, transmission component 1504 depicted and described in connection with FIG. 15), among other examples. In some other aspects, the means for the first network entity to perform operations described herein may include, for example, one or more of communication manager 255, processing system 245, processing system 110, communication manager 114, communication interface 116, processing system 112, communication manager 118, communication interface 120, a radio, one or more RF chains, one or more transceivers, one or more antennas, one or more modems, a reception component (for example, reception component 1602 depicted and described in connection with FIG. 16), or a transmission component (for example, transmission component 1604 depicted and described in connection with FIG. 16), among other examples.

In some aspects, the a network entity (e.g., a receiver, such as a UE 220 or a network node 210) includes means for receiving a signal that indicates first information associated with one or more constellation symbols; means for demodulating, based on the one or more constellation symbols, the first information to obtain encoded information; or means for decoding, based on a permutation pattern, the encoded information to obtain second information, wherein the permutation pattern is associated with columns of a base graph for a low-density parity check code. In some aspects, the means for the first network entity to perform operations described herein may include, for example, one or more of communication manager 250, processing system 240, processing system 110, communication manager 114, communication interface 116, processing system 112, communication manager 118, communication interface 120, a radio, one or more RF chains, one or more transceivers, one or more antennas, one or more modems, a reception component (for example, reception component 1502 depicted and described in connection with FIG. 15) or a transmission component (for example, transmission component 1504 depicted and described in connection with FIG. 15), among other examples. In some other aspects, the means for the first network entity to perform operations described herein may include, for example, one or more of communication manager 255, processing system 245, processing system 110, communication manager 114, communication interface 116, processing system 112, communication manager 118, communication interface 120, a radio, one or more RF chains, one or more transceivers, one or more antennas, one or more modems, a reception component (for example, reception component 1602 depicted and described in connection with FIG. 16), or a transmission component (for example, transmission component 1604 depicted and described in connection with FIG. 16), among other examples.

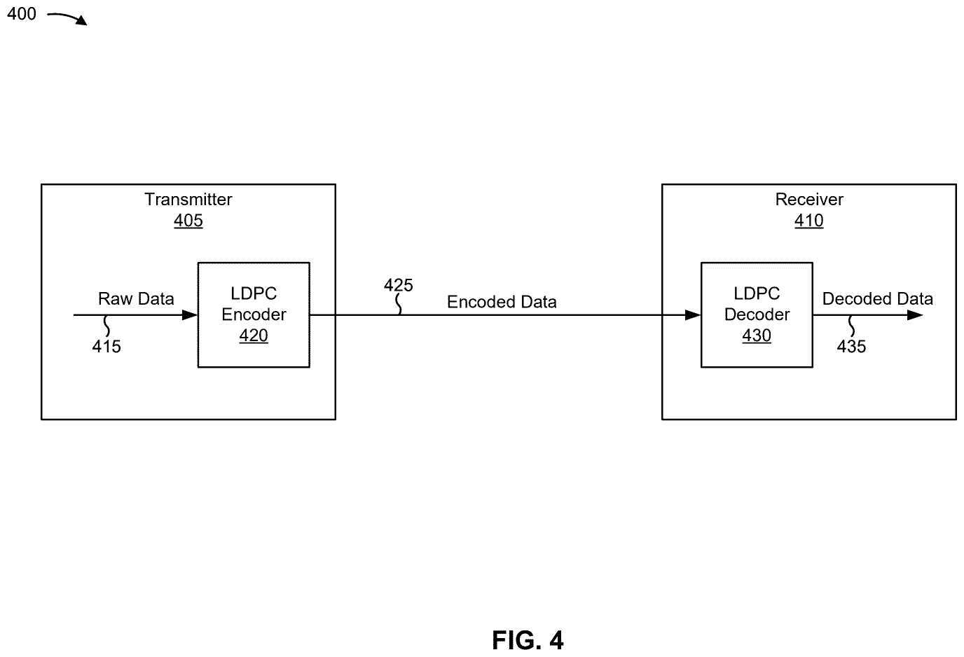

FIG. 4 is a diagram illustrating an example 400 of communication using LDPC codes. As shown in FIG. 4, example 400 includes communication between a first network entity, shown in FIG. 4 and referred to herein as transmitter 405, and a second network entity, shown in FIG. 4 and referred to herein as receiver 410. As shown in FIG. 4, the transmitter 405 includes an LDPC encoder 420 and the receiver 410 includes an LDPC decoder 430, which the transmitter 405 and the receiver 410 may use to implement an LDPC channel coding scheme in which LDPC codes are used for one or more data channel transmissions. For example, in some aspects, the transmitter 405 may correspond to a network node 210 and the receiver 410 may correspond to a UE 220, and the LDPC channel coding scheme may be used for one or more PDSCH transmissions from the network node 210 to the UE 220. Additionally, or alternatively, the transmitter 405 may correspond to a UE 220 and the receiver 410 may correspond to a network node 210, and the LDPC channel coding scheme may be used for one or more PUSCH transmissions from the UE 220 to the network node 210. Additionally, or alternatively, the transmitter 405 may correspond to a first UE 220 and the receiver 410 may correspond to a second UE 220, and the LDPC channel coding scheme may be used for one or more physical sidelink shared channel (PSSCH) transmissions from the first UE 220 to the second UE 220. In some aspects, the transmitter 405 and the receiver 410 may communicate in a wireless network, such as the wireless communication network 200.

In some aspects, a communication from the transmitter 405 to the receiver 410 may be encoded based at least in part on an error correcting code (sometimes referred to as an error correcting scheme), such that the receiver 410 can determine whether the communication was properly transmitted (e.g., to verify that the communication was not corrupted by noise or the like) or so that the receiver 410 can correct any transmission errors using redundant bits provided by the error correcting code. One example of an error correcting code is an LDPC code. A communication may be encoded according to an LDPC channel coding scheme to provide for error detection at the receiver 410. Encoding for an LDPC code may be performed based at least in part on a base graph (e.g., a sparse bipartite graph) that may identify a codeword to be generated from an input data set or information to append to an input data set to form the LDPC code.

More particularly, as shown in FIG. 4, the transmitter 405 may be in wireless communication with the receiver 410. When the transmitter 405 transmits data to the receiver 410, the transmitter 405 may first encode the data using an error correcting code, such as an LDPC code. For example, as shown in FIG. 4, the transmitter 405 may process raw data 415 (e.g., information bits) to be transmitted to the receiver 410 by feeding the raw data 415 through the LDPC encoder 420, among other signal processing components. The transmitter 405 may perform other signal processing operations (e.g., interleaving or the like), which are not shown in FIG. 4. The LDPC encoder 420 may add error correction bits (e.g., parity bits) to the raw data 415 based at least in part on a selected base graph or based at least in part on a target code rate, forming an encoded data stream 425. In some examples, the target code rate may be expressed as R=k/n, where R is the target code rate, k is a number of information bits in the raw data 415 input to the LDPC encoder 420, and n is a total number of bits in the encoded data stream transmitted to the receiver 410 (e.g., the target code rate is the proportion of the encoded data stream 425 that is useful, or non-redundant). For example, LDPC codes associated with a lower code rate provide more error protection, but may incur more overhead, relative to LDPC codes with a higher code rate.

As further shown in FIG. 4, the transmitter 405 may transmit the encoded data stream 425 to the receiver 410 over a wireless link (e.g., a wireless access link for uplink or downlink communication, or a wireless sidelink for sidelink communication), where the encoded data stream 425 is fed through the LDPC decoder 430 (and, in some examples, other signal processing components such as a de-interleaver, among other examples) in order to recover the information bits from decoded data 435 output from the LDPC decoder 430. For example, the LDPC decoder 430 may use an iterative belief propagation decoding scheme (also known as a message passing decoding scheme) to decode the encoded data stream 425.

As indicated above, FIG. 4 is provided as an example. Other examples may differ from what is described with regard to FIG. 4.

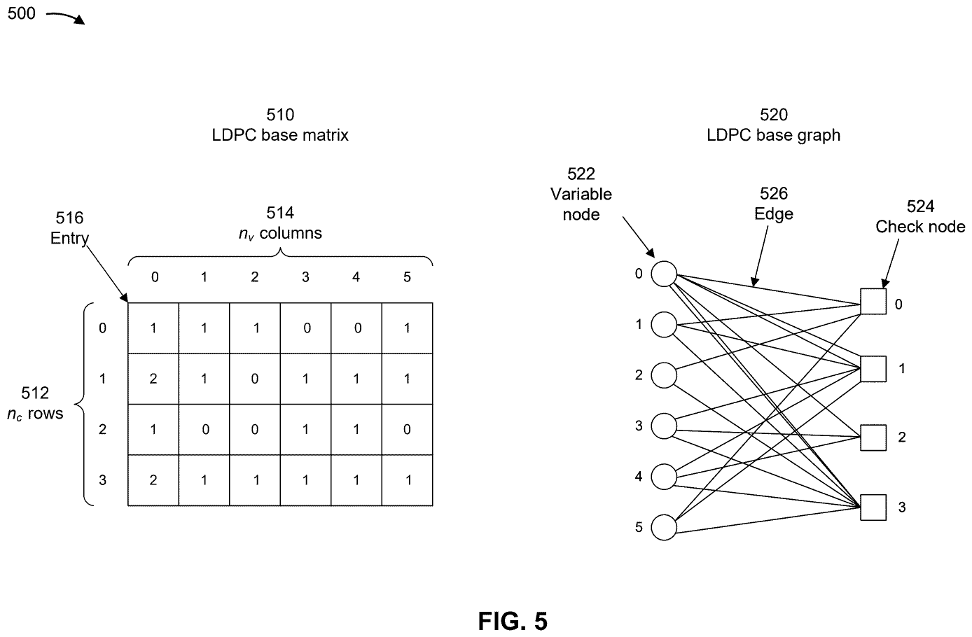

FIG. 5 is a diagram illustrating an example 500 of an LDPC base matrix 510 and an LDPC base graph 520. As described herein, the LDPC base matrix 510 and the LDPC base graph 520 may be used to encode an LDPC code, which is a linear block code that can provide error correction capabilities that may be close to channel capacity. For example, the LDPC base matrix 510 and the LDPC base graph 520 may be used by the LDPC encoder 420 of the transmitter 405 to encode the raw data 415 (e.g., to generate the encoded data stream 425). In some examples, an LDPC code may be represented according to a base graph (for example, a sparse bipartite graph) that may identify a codeword to be generated from an input data set or information to append to an input data set to form the LDPC code. For example, a bipartite graph may include variable nodes representing information bits (also known as message bits or systematic bits) and check nodes representing parity-check equations. The edges between the variable nodes and the check nodes may define how the information bits are related through the parity-check equations, which may be solved using the input data set to determine the values of the parity bits. For example, the original information bits may be combined with the parity bits to form an LDPC code containing the input data (information bits) and the error-correcting (parity) bits.

As shown in FIG. 5, the LDPC base matrix 510 has a size n_{c}×nᵥ including a total number of n rows 512 and a total number of nᵥ columns 514. Additionally, both n_{c} and nᵥ are positive integers, and the total number of rows n_{c} may be smaller than the total number of columns nᵥ. Each entry 516 of the LDPC base matrix 510 is a non-negative integer in a set of integers ranging from 0 to a bounded integer that is independent of the size of the LDPC base matrix 510. For example, the set of integers may be {0,1}, {0,1,2}, or {0,1,2, . . . , dₘₐₓ} for some dₘₐₓ integer. Additionally, each row 512 of the LDPC base matrix 510 may be indexed by a respective integer from 0 to n_{c}−1. Each column 514 of the LDPC base matrix 510 may be indexed by a respective integer from 0 to nᵥ−1.

As further shown in FIG. 5, the LDPC base matrix 510 is associated with an LDPC base graph 520 that represents the LDPC base matrix 510. In some examples, the LDPC base graph 520 may be a bipartite graph including a set of variable nodes 522, a set of check nodes 524, and a set of edges 526 connecting the set of variable nodes 522 and the set of check nodes 524. For example, each variable node 522 may be labelled by a respective integer from 0 to nᵥ−1, such that each variable node 522 corresponds to a column 514 of the LDPC base matrix 510. Furthermore, each check node 524 may be labelled by a respective integer from 0 to n_{c}−1, such that each check node 524 corresponds to a row 512 of the LDPC base matrix 510. Additionally, an edge 526 exists between a variable node i and a check node a if a value of the entry at (column a, row i) of the LDPC base matrix 510 is non-zero, and the number of edges between the variable node i and the check node a is equal to the value of the entry at (column a, row i) in the LDPC base matrix 510. For example, the entry at (column 0, row 0) of the LDPC base matrix 510 has a value of 1, which is represented in the edge 526 between variable node 0 and check node 0. Furthermore, a variable node 522 is a state node if a corresponding column 514 of the LDPC base matrix 510 is a state column. In addition, a state variable or state column may refer to a variable node of an LDPC code associated with a transmitted (e.g., punctured) set of information bits.

As indicated above, FIG. 5 is provided as an example. Other examples may differ from what is described with regard to FIG. 5.

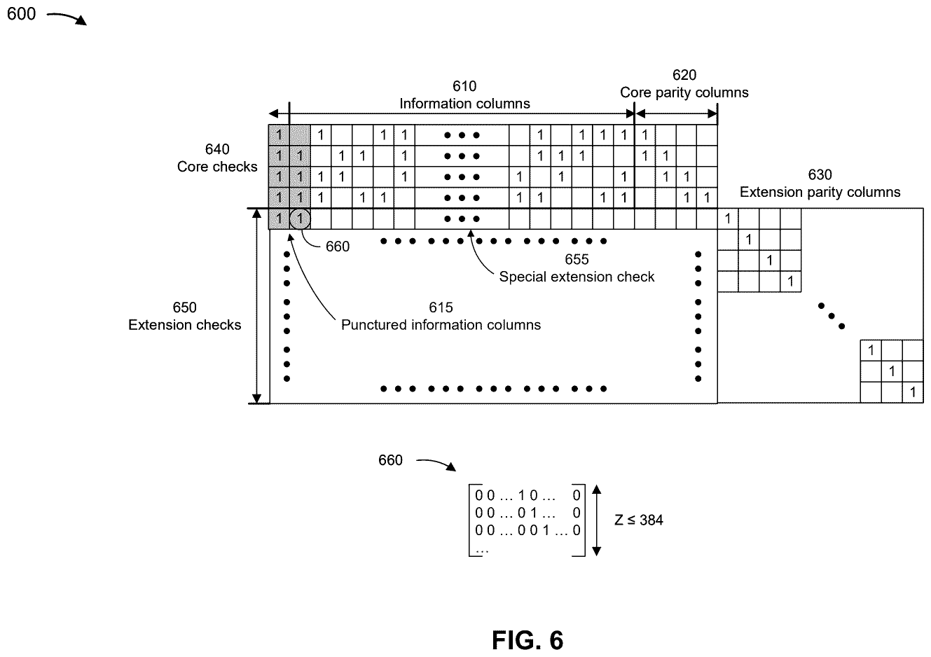

FIG. 6 is a diagram illustrating an example 600 of a PCM associated with an LDPC code. As described herein, the PCM shown in FIG. 6 may be used for a QC-LDPC code, where the PCM has a compact representation that may enable efficient LDPC encoding and high parallelism in a corresponding LDPC decoder architecture. In some examples, the PCM shown in FIG. 6 may be used by the transmitter 405 to encode the raw data 415 via the LDPC encoder 420. Similarly, the PCM shown in FIG. 6 may be used by the receiver 410 to decode the encoded data stream 425 via the LDPC decoder 430.

For example, the PCM is a set of codewords that satisfy one or more parity check conditions, which may be defined according to a base graph and lifting values (also known as a protograph LDPC code). In particular, as described herein, the base graph (or protograph) is a small graph that captures macroscopic properties associated with the QC-LDPC code, such as a decoding threshold. After the base graph has been constructed, a lifting procedure is applied in which the base graph is copied multiple times and connections between different copies of the base graph are permuted to construct one larger graph. Otherwise, without permuting the different copies of the base graph into one larger graph, there would be K small graphs that are not connected to each other, which may result in no coding gain. The copying and permutation is a cyclic permutation along edges of the base graph, and is generally known as cyclic shift lifting. Accordingly, the LDPC code resulting from the encoding procedure of constructing the base graph and applying the lifting procedure is known as a quasi-cyclic LDPC code.

In some examples, the base graph associated with an LDPC code (such as the LDPC base graph 520) may be described or represented as a matrix (or base matrix), such as the PCM shown in example 600. For example, as shown in FIG. 6, the PCM includes a set of information columns 610, a set of core parity columns 620, and a set of extension parity columns 630, which represent variable nodes associated with the PCM. In addition, the PCM includes a set of core check rows 640 and a set of extension check rows 650, which represent check nodes associated with the PCM. The extension check rows 650 include a special extension check 655, and the information columns include one or more punctured information columns 615. For each entry in the PCM, the value is a non-negative integer representing the number of connections between the variable node and the check node corresponding to the entry (e.g., a 0 means that there is no connection between the corresponding variable node and check node, a 1 means that there is 1 edge connecting the corresponding variable node and check node, a 2 means that there are 2 edges connecting the corresponding variable node and check node, and so on). As described herein, each variable node has a degree that denotes the number of check nodes that the variable node is connected to in the base graph (e.g., the number of rows with a positive value), where a degree-n variable node is connected to n check nodes. The extension check rows 650 include a special extension check 655, and the information columns include one or more punctured information columns 615.

As further shown in FIG. 6, and by reference number 660, each entry that has a positive value (e.g., one) may be replaced by a permuted identity matrix that indicates the number of cyclic permutations applied to each edge in the base graph. The lifting values may be integers in a range between 0 and Z, where Z is a lifting factor (e.g., the number of copies that are applied to the base graph). Accordingly, after constructing the base graph and applying the lifting procedure, the resulting QC-LDPC code has a block length equal to the size of the base graph multiplied by the lifting factor.

As indicated above, FIG. 6 is provided as an example. Other examples may differ from what is described with regard to FIG. 6.

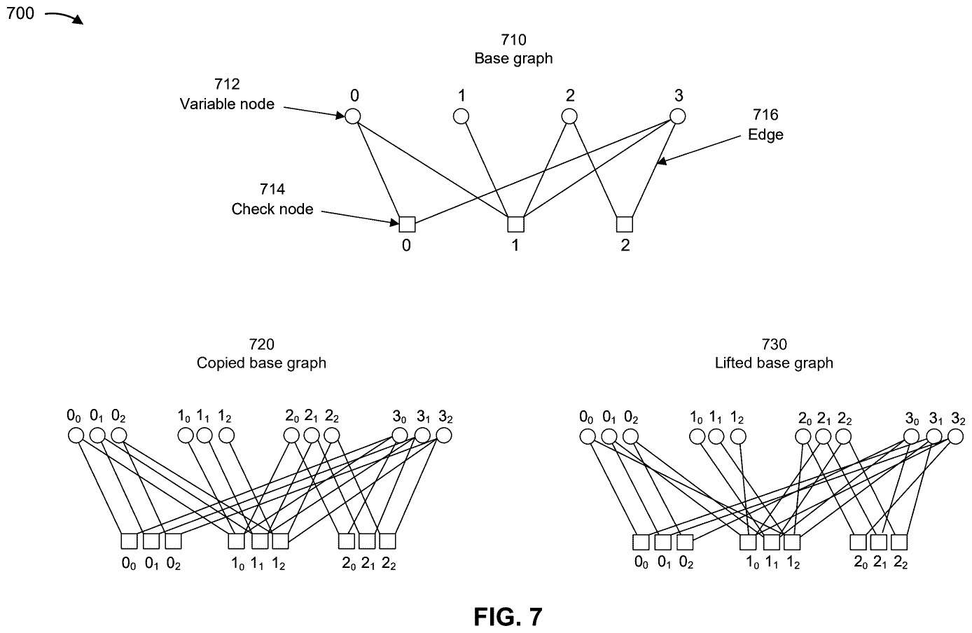

FIG. 7 is a diagram illustrating an example 700 of lifting for an LDPC code. As described herein, an LDPC code is a binary linear block code over a finite field F₂, and protograph-based QC-LDPC codes are a type of LDPC code used in various communication systems (e.g., NR, Wi-Fi, and Ethernet). For example, to generate a QC-LDPC code, a cyclic lifting operation may be performed over a base graph 710 (e.g., the LDPC base graph 520) or a protograph to generate a lifted base graph 730 by taking Z copies of the base graph 710. For example, the Z copies of the base graph 710 may be taken to generate a copied base graph 720, which includes one or more copies of each variable node 712, each check node 714, and each accompanying edge 716 in the base graph 710 or protograph. In some examples, Z is a lifting factor selected from a set of lifting factors, which may determine how many bits are represented for each bit in the original code. The Z like or similar edges of the copied base graph 720 may be connected through respective cyclic permutations to generate the lifted base graph 730.

For example, the Z graphs in the copied base graph 720 are interconnected to form a larger graph in which each variable node 712 in one copy of the base graph 710 (in the copied base graph 720) is connected to a check node 714 in another copy of the base graph 710 only if the variable node 712 is connected to the check node 714 in the original base graph 710. In other words, for each variable node 712 and check node 714 that are connected in the base graph 710, the Z edges 716 are permuted among the variable nodes 712 and the check nodes 714 that correspond to the same variable node 712 and check node 714 in the base graph 710. Furthermore, to reduce encoding and decoding complexity, the permuting operation may be limited to cyclic lifting, where the permutation is a cyclic shift (e.g., where each non-zero entry in the base graph 710 is replaced with a Z×Z circulant matrix, as shown in FIG. 6). Accordingly, in a QC-LDPC code, each edge 716 in the base graph 710 may have a cyclic shift value.

In some examples, the lifted base graph 730 indicates a lifted PCM and an associated QC-LDPC code. In some examples, one or more telecommunications standards may define an LDPC code design that includes QC-LDPC codes with two base graphs (for example, BG1 and BG2) and a cluster of sets of lifting factors. In some examples, a cyclically lifted LDPC code over [symbol] , based on an LDPC base matrix or an LDPC base graph (such as base graph 710), can be represented as a code over a group ring [symbol] [x] that may include all binary polynomials modulo x^{Z}+1 over [symbol] . In this representation, each variable node 712 in the base graph 710 can be represented as a binary polynomial b=b₀+b₁x+b₂x²+ . . . +b_{Z-1}x^{Z-1}, where [b₀, . . . , b_{Z-1}] denotes the Z bits associated with Z variable nodes 712 in the lifted base graph 730. Furthermore, cyclically shifting the vector [b₀, . . . , b_{Z-1}] by an element t is equivalent to multiplying the polynomial b by x^{t}. Accordingly, a PCM with lifting values may be represented as

$$[ \begin{matrix}{x}^{{a}_{00}} & 0 & {x}^{{a}_{02}} & 0 \\ 0 & {x}^{{a}_{11}} & {x}^{{a}_{12}} & {x}^{{a}_{13}} \\ {x}^{{a}_{20}} & {x}^{{a}_{21}} & {x}^{{a}_{22}} & 0 \\ {x}^{{a}_{30}} & {x}^{{a}_{31}} & 0 & {x}^{{a}_{33}}\end{matrix} ] ,$$

or equivalently represented as

$$[ \begin{matrix}{a}_{00} & - 1 & {a}_{02} & - 1 \\ - 1 & {a}_{11} & - 1 & {a}_{13} \\ {a}_{20} & {a}_{21} & {a}_{22} & - 1 \\ {a}_{30} & {a}_{31} & - 1 & {a}_{33}\end{matrix} ] ,$$

where aᵢⱼϵ{0, . . . , Z−1} denotes the lifting values (or cyclic shift values) and a −1 value denotes no edge between the variable node and the check node (e.g., no edge 716 between the variable node 712 and the check node 714 in the base graph 710 or the lifted base graph 730). For example, the above representations indicate that the first edge (the entry in the upper-left corner) is cyclically shifted by an integer a₀₀, and the last edge (the entry in the lower-right corner) is cyclically shifted by an integer a₃₃.

The LDPC polynomial matrix code contains the set of all length-nᵥ vectors over [symbol] [x], C(x), such that H(x)C(x)≡0, where H(x) is an LDPC polynomial matrix of size n_{c}×nᵥ over [symbol] [x]. Each entry of the LDPC polynomial matrix may be a polynomial in [symbol] [x], and the number of non-zero terms of the polynomial may be given by the corresponding entry of the base matrix, where each exponent of the polynomial may be referred to as a cyclic shift value. Additionally, a lifted LDPC matrix, denoted H, may be defined by replacing each element of the LDPC base matrix by a respective permutation matrix of size Z×Z, where the amount (e.g., sum) of permutations is indicated by the respective exponents of the LDPC polynomial matrix. For example, an LDPC polynomial matrix, denoted H(x), may have a one-to-one correspondence with a lifted LDPC matrix H and may specify a lifted LDPC code over [symbol] .

As indicated above, FIG. 7 is provided as an example. Other examples may differ from what is described with regard to FIG. 7.

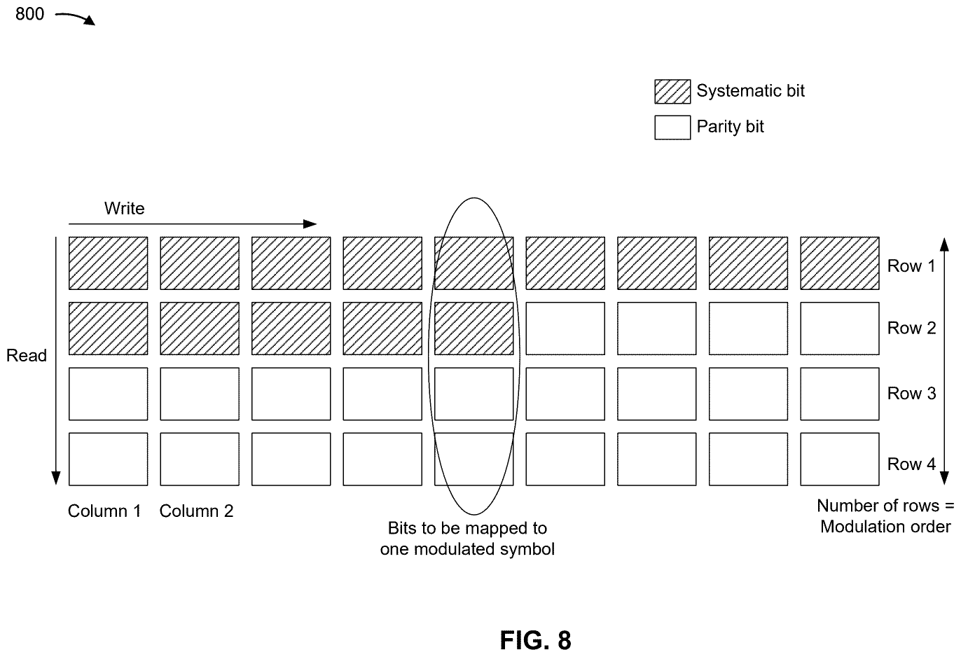

FIG. 8 is a diagram illustrating an example 800 of interleaving. In some examples, interleaving may be performed after (or as the last step of) rate matching to map bits to symbols for modulation. Interleaving may improve reliability of a transmitted communication by, for example, improving robustness of forward error correction at a receiver, such as the receiver 410. For example, interleaving may result in bits, which are consecutive prior to interleaving, being spaced out (e.g., in MIMO layers, frequency, or time) such that some of those bits are no longer consecutive. This may mitigate the effects of burst errors, thereby reducing local gaps in communications, such as gaps in voice, video, data, or other communications.

A communication transmitted over the air may include systematic bits (e.g., also referred to as information bits or message bits) and parity bits (e.g., also referred to as check bits), which together form coded bits (e.g., a codeword) of the communication. The systematic bits may carry the information to be conveyed, and the parity bits may be used for error detection or error correction (e.g., using a checksum, or a cyclic redundancy check). In some aspects, the parity bits are a function of or determined based at least in part on the systematic bits.

SBPM is a technique to map systematic bits of a communication to the most significant bits of each modulated symbol of the communication. This increases reliability due to an increased likelihood of correct demodulation of the systematic bits because the most significant bits (e.g., the most significant bit, or one or more most significant bits) of the modulated symbol have increased protection against errors as compared to the least significant bits (e.g., the least significant bit, or one or more least significant bits) of the modulated symbol when using conventional modulation constellations, such as PSK or QAM. For example, even if a receiver incorrectly demodulates a modulated symbol, that incorrect demodulation is likely to correspond to a constellation point, in a constellation diagram for the conventional modulation scheme, that is near the correct constellation point and that has one or more most significant bits in common with the correct constellation point. SBPM may be referred to as a bit-to-modulation mapping technique. For example, SBPM may be a technique for mapping coded bits (e.g., bits from the encoded data stream 425) to modulation constellation symbols for over-the-air transmission.

An example of SBPM interleaving (e.g., using block interleaving) is shown in FIG. 8. In some examples, SBPM interleaving may be referred to as a depth-m block interleaving. In example 800, each block represents a bit, which may be a systematic bit or a parity bit, as shown. A column of blocks represents a number of bits that are mapped to a single symbol (e.g., a single modulated symbol). The number of bits (e.g., the number of rows in a column) is equal to the modulation order. Thus, interleaving may be a function of modulation order. In example 800, each modulated symbol represents 4 bits, which has a modulation order of 4 (e.g., 4 bits per symbol). The number of columns may depend on the size of the communication to be transmitted. For example, the number of columns may be equal to the total number of coded bits (e.g., systematic bits plus parity bits) to be transmitted, divided by the modulation order. In example 800, there are 36 coded bits to be transmitted with a modulation order of 4, leading to 9 columns of blocks.

In some aspects, block interleaving (e.g., SBPM interleaving) may be performed using a technique called write by row, read by column. Using this technique, bits may be obtained from a circular buffer as part of a rate matching process, with a starting bit determined based at least in part on a redundancy version, of the communication, to be transmitted. As the bits are obtained, those bits may be written to blocks across a first row (shown as row 1), where each bit is placed in a different column corresponding to a different symbol. After the first row is filled, bits may be written to blocks across a second row (shown as row 2), and so on. The starting bit and a set of subsequent bits of the circular buffer may be systematic bits, and may be followed by parity bits. As a result, the first one or more rows (shown toward the top of FIG. 8) may include systematic bits, and the last one or more rows (shown toward the bottom of FIG. 8) may include parity bits.

Because the first row(s) correspond to more significant bits (e.g., MSBs) of the modulated symbol and the last row(s) correspond to less significant bits (e.g., LSBs) of the modulated symbol, this technique may map systematic bits (e.g., some, most, or all of the systematic bits, depending on a starting bit in the circular buffer) to the most significant bit(s) of the modulated symbol, thereby increasing reliability, as described above. In example 800, the first row corresponds to the MSB of the modulated symbol, and is filled entirely with systematic bits, and the last row corresponds to the LSB of the modulated symbol, and is filled entirely with parity bits.

After all of the coded bits are written to the blocks, referred to as interleaving, those interleaved bits are read from the blocks down a first column (e.g., shown as column 1) as input to a modulation process to modulate those coded bits in a modulated symbol. After modulation, the coded bits in the first column will be represented as a first modulated symbol, the coded bits in a second column (e.g., shown as column 2) will be represented as a second modulated symbol, and so on. In some aspects, the interleaving or the modulation may be performed to first map the modulated symbols to a layer (e.g., a MIMO layer), then map the modulated symbols to a frequency, and then map the modulated symbols to time. In this way, protection from burst errors may be enhanced.

As an example, an SBPM scheme may enable a transmitter (e.g., the transmitter 405 via the LDPC encoder 420) to map the systematic portion of coded bits (e.g., LDPC coded bits) to the MSB of a modulation constellation, and to map the non-systematic portion to the LSB of the modulation constellation. Without applying SBPM, each variable node in the base graph may experience, on average, the same channel conditions or reliabilities. As a result of applying SBPM, copies of the same variable node in a base graph (such as a variable node 712 in the base graph 710) may be associated with similar channel reliabilities and different variable nodes in the base graph may experience different channel reliabilities. For example, in the lifted base graph 730 depicted in FIG. 7, the variable nodes 0₀, 0₁, and 0₂ may be mapped to an MSB and the variable nodes 3₀, 3₁, and 3₂ may be mapped to an LSB. Without SBPM, the variable nodes 0₀, 0₁, 3₁, and 3₂ may be mapped to one modulation constellation symbol (e.g., one QAM symbol). By improving likelihood of copies of the same variable node in a base graph being associated with similar channel reliabilities (e.g., by mapping them consistently to the MSB or LSB, for example), the SBPM scheme may improve a decoding threshold for a channel coding scheme, such as the QC-LDPC coding scheme described herein.

However, an SBPM scheme can result in performance degradation in some scenarios, such as high throughput scenarios (e.g., throughputs above 100 gigabits per second). For example, an SBPM scheme may result in degraded performance for transport block sizes near a switch point between two base graphs for an LDPC code. The switch point may be a threshold transport block size. For example, if a transport block has a size less than the threshold transport block size, a transmitter may encode the transport block using a first base graph. If the transport block has a size greater than the threshold transport block size, the transmitter may encode the transport block using a second base graph. For transport block sizes near the switch point, data encoded using the first base graph may experience worse performance (e.g., worse SNR performance) than data encoded using the second base graph (e.g., there may be a jump in performance near the switch point when switching to the second base graph). The jump or increase in performance may be caused by the SBPM scheme, rather than the LDPC encoding. Such jumps or increases in SNR performance may cause degraded performance for communications between the transmitter and the receiver because fluctuations in SNR conditions can cause degrade the decoding processing, increasing the risk of decoding errors, among other examples. Additionally, or alternatively, the SBPM scheme may be associated with a higher error floor (e.g., a higher minimum block error rate supported). For example, SBPM may result in degraded performance in low error rate scenarios. As another example, for a probabilistic shaping system that uses QC-LDPC codes, SBPM may be inapplicable because SBPM may result in parity bits being mapped to an LSB.

As indicated above, FIG. 8 is provided as an example. Other examples may differ from what is described with regard to FIG. 8.

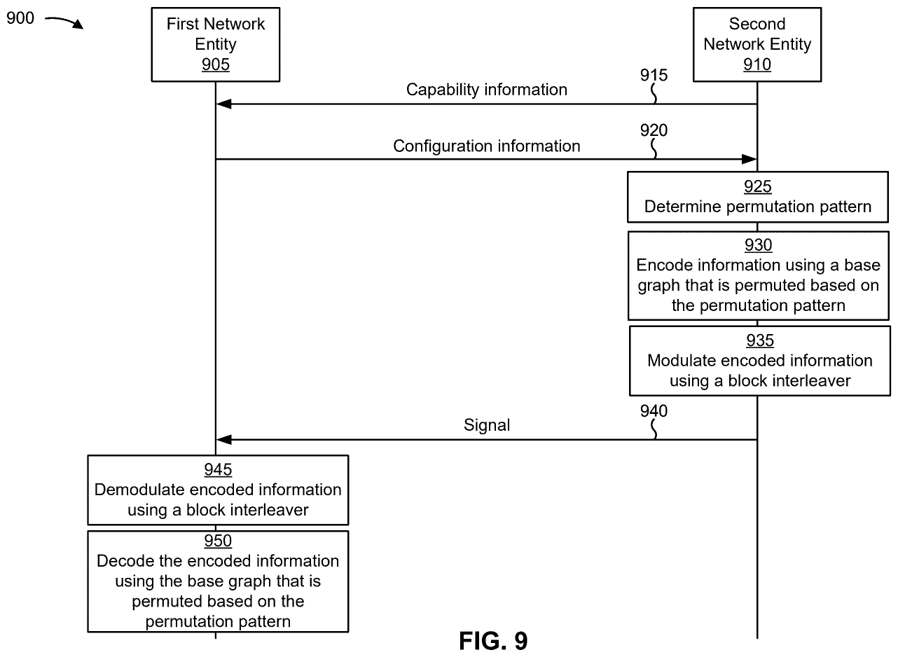

FIG. 9 is a diagram of an example 900 associated with permutations for an LDPC code. As shown in FIG. 9, a first network entity 905 (e.g., the network entity 106, the network entity 102, a network node 210, a UE 220, the receiver 410, a CU, a DU, or an RU) may communicate with a second network entity 910 (e.g., the network entity 102, the network entity 106, a network node 210, a UE 220, the transmitter 405, a CU, a DU, or an RU). In some aspects, the first network entity 905 and the second network entity 910 may be part of a wireless network (e.g., the wireless communication network 200 or the environment 100). The second network entity 910 and the first network entity 905 may have established a wireless connection prior to operations shown in FIG. 9.

In some aspects, as shown by reference number 915, the second network entity 910 may transmit capability information. The capability information may be included in a capability report. The second network entity 910 may transmit the capability information via an uplink communication, a sidelink communication, a unicast communication, a broadcast communication, a UE assistance information (UAI) communication, an uplink control information (UCI) communication, a sidelink control information (SCI) communication, a MAC control element (MAC-CE) communication, an RRC communication, a physical uplink control channel (PUCCH), a physical uplink shared channel (PUSCH), a physical sidelink control channel (PSCCH), or a physical sidelink shared channel (PSSCH), among other examples. The capability information may indicate one or more parameters associated with respective capabilities of the second network entity 910. The one or more parameters may be indicated via respective information elements (IEs) included in a capability report.

The capability information may indicate whether the second network entity 910 supports a feature or one or more parameters related to the feature. For example, the capability information may indicate a capability or parameter for permutations for a low-density parity check code. As another example, the capability information may indicate a capability or parameter for SBPM or PAS. One or more operations described herein may be based on capability information. For example, the second network entity 910 may perform a communication in accordance with the capability information, or may receive configuration information that is in accordance with the capability information. In some aspects, the capability information may indicate support for encoding first information to obtain encoded information, modulating the encoded information to map the encoded information to one or more constellation symbols, or transmitting a signal that indicates second information that is based on the one or more constellation symbols. In some aspects, the capability information may indicate one or more premutation patterns supported by the second network entity 910.

As shown by reference number 920, the first network entity 905 may transmit, and the second network entity 910 may receive, configuration information. In some aspects, the second network entity 910 may receive the configuration information via one or more of system information signaling (e.g., a master information block (MIB) or a system information block (SIB), among other examples), RRC signaling, MAC signaling (e.g., one or more MAC-CEs), or physical layer signaling (e.g., DCI), among other examples.

In some aspects, the configuration information may indicate one or more candidate configurations or communication parameters. In some aspects, the one or more candidate configurations or communication parameters may be selected, activated, or deactivated by a subsequent indication. For example, the subsequent indication may select a candidate configuration or communication parameter from the one or more candidate configurations or communication parameters. In some aspects, the subsequent indication may include a dynamic indication, such as one or more MAC-CEs or one or more DCI messages, among other examples.

In some aspects, the configuration information may include an indication of a selection of one or more configuration parameters (e.g., a selection of the one or more configuration parameters already known to the second network entity 910 or previously indicated by the network node or other network device), or explicit configuration information for the second network entity 910 to use to configure the second network entity 910, among other examples.

In some examples, the configuration information may not be expressly signaled to the second network entity 910. For example, in some aspects, the configuration information may at least partially be defined by a wireless communication standard, such as the 3GPP. In such examples, the first network entity 905 may not explicitly indicate such configuration information to the second network entity 910. For example, the second network entity 910 may optionally obtain at least a portion of the configuration information from a configuration stored by the second network entity 910 (e.g., an original equipment manufacturer (OEM) configuration). In some aspects, the configuration information may include a parameter or index that is indicative of information defined, or otherwise fixed, by a wireless communication standard, such as the 3GPP (e.g., rather than explicitly indicating the information).

In some aspects, the configuration information may indicate that the second network entity 910 is to use a permuted base graph for an encoding operation (e.g., an LDPC encoding operation or a QC-LDPC encoding operation). For example, the permutation pattern can be pre-defined and stored in the memory of the second network entity 910. Additionally, or alternatively, the first network entity 905 may dynamically provide the permutation pattern through signaling, such as RRC signaling, MAC-CE signaling, or DCI signaling. In some aspects, the configuration information may indicate a base graph to be used by the second network entity 910 for LDPC encoding. For example, the configuration information may indicate a base graph and a permutation pattern to be applied for the base graph. By the second network entity 910 applying this permutation pattern, the second network entity 910 can improve the likelihood that certain parity columns in a base graph are placed at the beginning of the base graph, which can improve bit-to-constellation mapping and improving the error floor performance by improving the likelihood that such parity columns are mapped to MSBs in constellation symbols.

In some aspects, the configuration information may define or indicate one or more permutation patterns. In some aspects, permutation patterns may be defined or configured for respective transmission parameters. The transmission parameters may include an MCS, a base graph, a modulation order, or an MCS-base graph pair. By defining or configuring permutation patterns based on various transmission parameters, the first network entity 905 or the second network entity 910 can dynamically adjust the encoding operation (e.g., the permutation pattern being applied) different transmission conditions and requirements. This adaptability enhances spectral efficiency, reduces transmission errors, or improves the overall robustness and reliability of data transmission, among other examples, because the encoding operation (e.g., the permutation pattern being applied) may be optimized for the transmission parameter(s).

In some aspects, permutation patterns may be defined or configured for respective MCS-base graph pairs. For example, for a given MCS-base graph pair, one or more permutation patterns may be defined or configured. As an example, a different permutation pattern may be defined or configured for each available MCS-base graph pair (e.g., a table may define a permutation pattern for each available MCS-base graph pair). As another example, different permutation patterns can be defined for different modulation orders and base graphs. For example, the second network entity 910 can select a permutation pattern based on the modulation order and the base graph configured for use. As another example, the permutation patterns may be defined or configured for respective base graphs. For example, the second network entity 910 can select a permutation pattern based on the base graph to be used by the second network entity 910.

In some aspects, a single permutation pattern may be defined or configured. The configuration information may indicate one or more base graphs, one or more MCS-base graph pairs, or other transmission parameters for which the permutation pattern is to be applied. For other transmission parameters (e.g., for other MCS-base graph pairs), the second network entity 910 may not apply a permutation pattern, but may apply SBPM interleaving, such as described in connection with FIG. 8.

In some aspects, the permutation pattern may be associated with a base graph. For example, the permutation pattern may indicate a re-ordering or permutation of columns of the base graph. Alternatively, the permutation pattern may be associated with a lifted graph (such as the lifted base graph 730). For example, the permutation pattern may indicate a re-ordering or permutation of columns of the lifted graph. In other words, the permutation may be applied across encoded bits (e.g., indicated by the lifted graph).

In some aspects, the configuration information may indicate one or transmission parameters to be used by the second network entity 910, such as for signals to be transmitted or received by the second network entity 910 (e.g., the signal described in connection with reference number 940). For example, the configuration information may indicate the MCS, the base graph, or the modulation order, among other examples to be used by the second network entity 910. This allows the second network entity 910 to adapt the permutation pattern based on the specific requirements of the transmission scenario. For example, different permutation patterns may be used for different MCSs or modulation orders to ensure that the most reliable bits are mapped to the MSB positions within the modulation constellation. This adaptability can enable high performance across various operating conditions.

In some aspects, the configuration information may indicate that the second network entity 910 is to perform an interleave operation (e.g., in addition to applying the permutation pattern for the base graph). This interleave operation can be a block interleave operation that further optimizes the placement of encoded bits within the modulation symbols (e.g., the interleave operation may be similar to SBPM interleaving described in connection with FIG. 8).

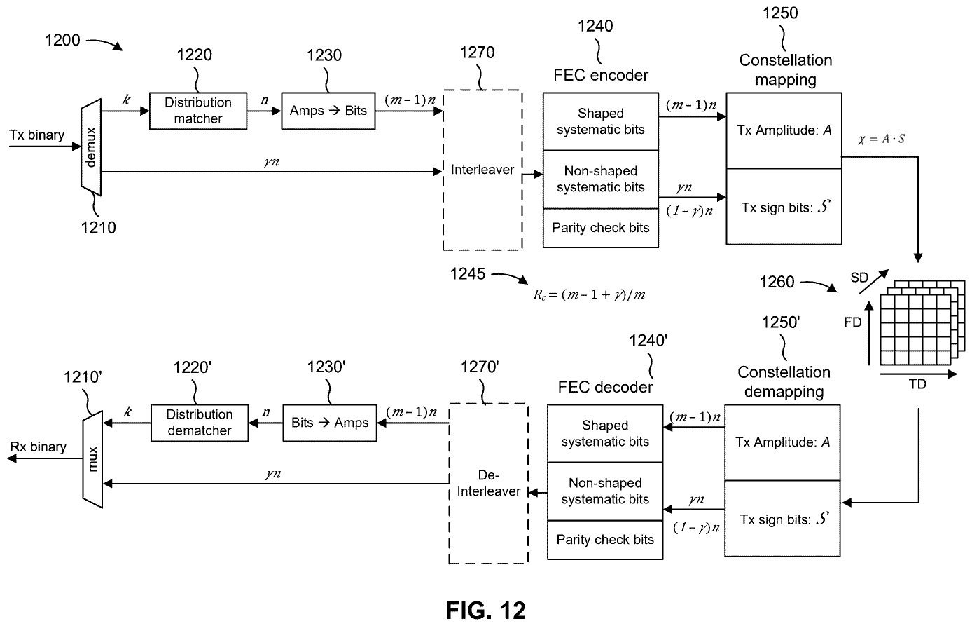

In some aspects, the configuration information may indicate that the second network entity 910 is to perform a probabilistic shaping (e.g., a PAS) operation. In such examples, the permutation pattern may be associated with the PAS operation. For example, one or more permutation patterns may be defined or configured for PAS operations. In such examples, the second network entity 910 may perform an interleave operation for shaped information (e.g., before an encoding operation) as part of the PAS operation. This enables the second network entity 910 to match the reliability of the uncoded shaped bits to the reliability of the columns of the base graph. The PAS operation is depicted and described in more detail in connection with FIG. 12.

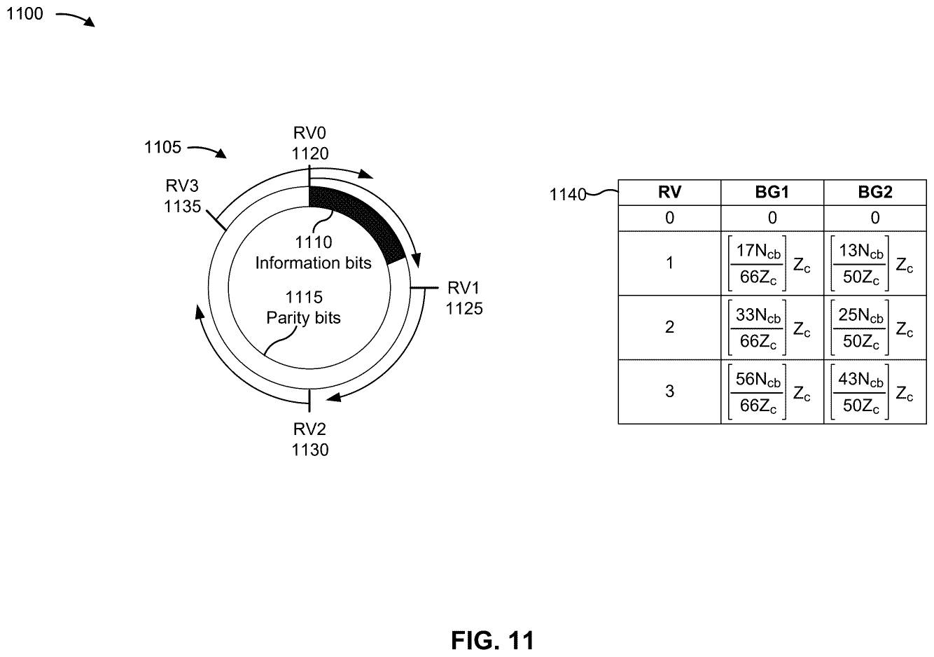

In some aspects, the configuration information may indicate permutation patterns for respective redundancy versions (e.g., HARQ redundancy versions). For example, multiple permutation patterns may be configured or defined. The multiple permutation patterns may be associated with respective redundancy versions of multiple redundancy versions. In other words, the second network entity 910 may be configured to use different permutation patterns (e.g., different column permutations for a base graph) for different redundancy versions. The application of the permutation patterns for different redundancy versions is depicted and described in more detail in connection with FIG. 11.

The second network entity 910 may configure itself based at least in part on the configuration information. In some aspects, the second network entity 910 may be configured to perform one or more operations described herein based at least in part on the configuration information.

In some aspects, the first network entity 905 may transmit, and the second network entity 910 may receive, an indication to apply permutation for a base graph for an encoding operation. The indication to apply the permutation for the base graph may be included in an RRC communication, a MAC-CE communication, or a DCI communication, among other examples. For example, the first network entity 905 may dynamically indicate whether the second network entity 910 is to apply a permutation pattern for columns of a base graph (e.g., to use a permutated base graph) for an LDPC encoding operation.

In some aspects, the first network entity 905 may transmit, and the second network entity 910 may receive, an indication to apply the permutation pattern for a base graph in addition to a block interleave operation (e.g., a depth-m block interleave operation, such as SBPM interleaving as described in connection with FIG. 8). For example, the second network entity 910 may dynamically switch between SBPM interleaving (e.g., as described in connection with FIG. 8) and other permutation patterns (e.g., a permutation pattern for a base graph or a lifted graph) for LDPC encoding based on one or more indications from the first network entity 905 or another network entity (such as a network node 210).

As shown by reference number 925, the second network entity 910 may determine a permutation pattern to be applied. The second network entity 910 may determine the permutation pattern based on one or more transmission parameters (e.g., indicated by the configuration information). For example, the second network entity 910 may determine the permutation pattern based on the MCS, the base graph (e.g., the type of base graph used for encoding), the modulation order, the SNR of the communication channel, or the redundancy version to be used for transmitted data, among other examples. By determining the permutation pattern based on the one or more transmission parameters, the second network entity 910 can determine (or select) an optimal permutation pattern that enhances the performance of the communication link.

For example, if the modulation order is high (e.g., 64QAM or 256QAM), the permutation pattern may be chosen to prioritize the mapping of systematic bits to more reliable positions within the modulation constellation, thereby improving the overall error performance. Similarly, if the base graph type changes due to varying data rates or payload sizes, the permutation pattern can be adjusted to ensure that the parity bits are mapped to appropriate positions to maintain a desired error correction performance.

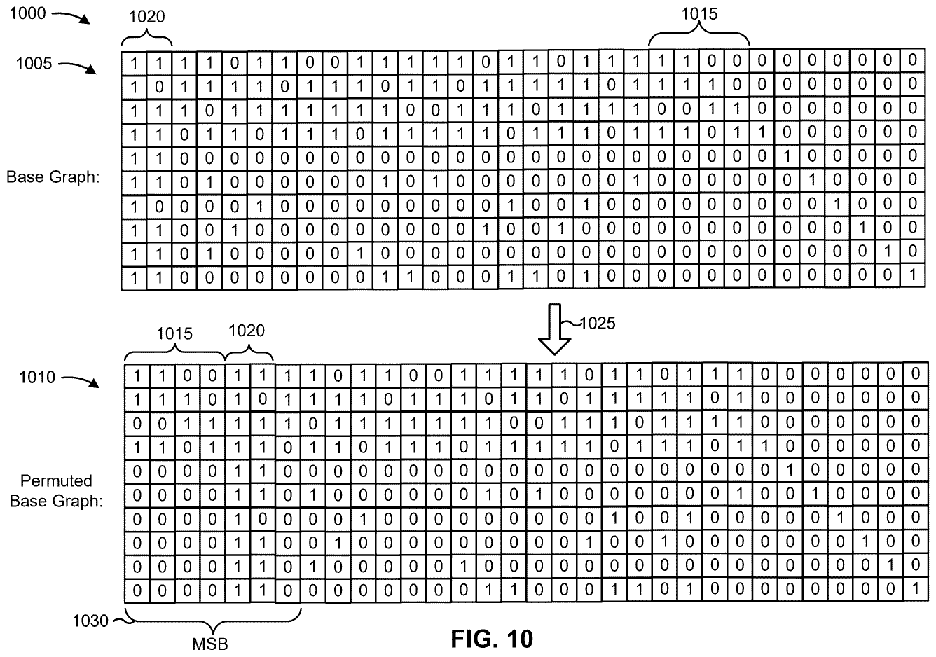

In some aspects, the permutation pattern may indicate an order (or re-ordering) of columns of a base graph to be used for encoding. For example, the permutation pattern may indicate a permuted order of the columns of the base graph. In some aspects, the permuted order may include one or more parity columns of the base graph at a start of the base graph. The one or more parity columns may be one or more core parity columns. In some aspects, the one or more parity columns may be second degree parity columns. For example, the base graph may include a set of second degree parity columns. The permutation pattern may indicate that a subset of second degree parity columns, from the set of second degree parity columns, are to be placed at, or near (e.g., after one or more punctured columns), the start of the base graph (e.g., as depicted in FIG. 10). In some aspects, the subset of second degree parity columns may be parity columns corresponding to a degree-2 parity chain and a degree-3 terminating variable node.

The re-ordering of parity columns (such as core parity columns) may improve the performance of encoded data. Core parity columns enable error correction capabilities for LDPC code. By positioning these parity columns (e.g., one or more core parity columns) at, or near, the start of the base graph, the permutation pattern improves the likelihood that the parity column(s) are mapped to the more reliable positions within the modulation constellation (e.g., to MSB positions). This improves the robustness of the transmitted signal, thereby reducing the likelihood of errors during data transmission.

In some aspects, one or more columns of the base graph may be permuted such that variable nodes corresponding to a second degree (e.g., degree-2) parity chain (e.g., including a third degree terminating variable node), are positioned at, or near, the beginning of the base graph. This re-ordering may improve the performance of LDPC codes by improving the reliability of the parity bits included in such columns. By mapping these parity columns to the MSBs of the modulation constellation, the second network entity 910 may improve the likelihood that error-prone bits receive the highest level of protection, thereby enhancing the overall error correction capability of the LDPC code. For example, second degree parity bits (or nodes) are connected to only two check nodes, which means that each bit in these columns participates in just two parity-check equations. This limited connectivity makes second degree parity bits (or nodes) more susceptible to errors, such as in noisy channel conditions. By re-ordering the parity columns such that variable nodes associated with second degree nodes are mapped to more reliable positions within the modulation constellation, such as the MSBs, the second network entity 910 can enhance the robustness of such bits against transmission errors.

In some aspects, the permutation pattern may indicate that one or more columns that are to be permuted or re-ordered are associated with first degree variable nodes (e.g., degree-1 nodes). For example, for lower coding rates or modulation orders (such as for 16QAM modulation with a coding rate that is less than a threshold, such as 0.5), the permutation pattern may indicate that one or more columns that are to be permuted or re-ordered are associated with first degree variable nodes (e.g., degree-1 nodes).

In some aspects, the permutation pattern may indicate that the one or more parity columns are placed at the start or beginning of the base graph (e.g., as depicted in FIG. 10). In some other aspects, the permutation pattern may indicate that the one or more parity columns are placed after one or more punctured columns within the base graph. This placement enables the second network entity 910 to map these column(s) to the MSBs of the constellation.

By the second network entity 910 using a base graph that includes the one or more columns (e.g., the one or more parity columns or core parity columns), the second network entity 910 may improve the likelihood that the columns are mapped to more reliable positions in a constellation symbols. For example, re-ordering or permuting the one or more columns near the start of the base graph enables the second network entity 910 to map the column(s) to an MSB and leverage the inherent reliability hierarchy of the modulation constellation. For example, in higher-order modulation schemes, such as 64QAM or 256QAM, the MSBs may be more reliable than the LSBs due to the MSBs lower susceptibility to noise and interference. By placing the one or more columns in these more reliable positions, the second network entity 910 may improve the likelihood that the most error-prone bits are afforded the highest level of protection.

Additionally, permuting or re-ordering the one or more columns can mitigate an error floor phenomenon of QC-LDPC codes, which is a lower limit to the bit error rate achievable by the code. The error floor may be caused by the presence of low-degree nodes, such as second degree nodes, which are more prone to forming small error-prone structures in a bipartite graph of the LDPC code. By mapping one or more columns to an MSB position, the error-prone structures can be broken up, thereby lowering the error floor and enabling the LDPC code to achieve lower error rates.

As shown by reference number 930, the second network entity 910 may encode information using a base graph that is permuted based on the permutation pattern. For example, the second network entity 910 may encode, based on the permutation pattern, the information to obtain encoded information (e.g., encoded bits). For example, the encoding may be based on the permutation pattern in that the second network entity 910 uses a base graph with permuted or re-ordered columns (e.g., where the permutation or re-ordering of the columns is indicated or based on the permutation pattern).

For example, the columns of the base graph may be permuted or re-ordered according to the specified pattern. This re-ordering or permutation may change the positions of one or more variable nodes within the base graph, effectively altering the structure of the LDPC code. The permutation pattern may prioritize the placement of certain variable nodes, such as degree-2 nodes or degree-1 nodes, to more reliable positions within the modulation constellation. By doing so, the encoding process ensures that these bits receive enhanced protection against transmission errors.

As an example, the permutation pattern for the LDPC code is generated using a predefined algorithm that optimizes the placement of parity bits. The algorithm begins by identifying the positions of the systematic and parity bits in the base graph. The columns of the base graph are then reordered such that the parity bits are placed in positions corresponding to the MSBs of the modulation constellation. This re-ordering is achieved by applying a cyclic shift operation to the columns of the base graph. For example, if the base graph has columns indexed from 0 to n−1, a cyclic shift by k positions would result in column i being moved to position (i+k) mod n. For example, consider a base graph with 8 columns, where columns 0 to 3 are systematic bits and columns 4 to 7 are parity bits. Applying a cyclic shift by 2 positions results in the new order: columns 2, 3, 4, 5, 6, 7, 0, 1. This reordered base graph is then used for the encoding process, ensuring that parity bits are placed in MSB positions.

In some aspects, the second network entity may expand the base graph through a lifting operation, where each entry in the base graph is replaced by a larger matrix, such as a circulant permutation matrix. The lifting operation creates a larger, quasi-cyclic LDPC code that retains the structural properties of the base graph while increasing the length and complexity.

In other aspects, the permutation may be applied after the lifting operation. For example, the permutation pattern may be applied to the lifted graph after the lifting operation is performed on the base graph (e.g., a base graph that does not include permuted or re-ordered columns). For example, the permutation pattern may indicate a re-ordering or permutation of one or more sets of encoded bits (e.g., where each set includes Z bits or columns, where Z is the lifting factor as described in connection with FIG. 8). This enables increased flexibility in optimizing the placement of variable nodes within the modulation constellation. By permuting the columns of the lifted graph, the encoding process can more precisely control the mapping of encoded bits to the MSBs of the constellation. This allows for a more tailored approach to enhancing the reliability of certain bits, such as parity bits, which can improve the error correction performance of the LDPC code.

The second network entity 910 may map information bits to the variable nodes of the lifted graph. The second network entity 910 may generate parity bits by solving the parity-check equations defined by the check nodes. The result of the encoding operation is a set of encoded bits (e.g., encoded information) that include both the original information bits and the generated parity bits.

As shown by reference number 935, the second network entity 910 may modulate the encoded information. For example, the second network entity 910 may modulate the encoded information (e.g., the encoded bits) to map the encoded information to one or more constellation symbols. In some aspects, the second network entity 910 may modulate the encoded information using a block interleaver. For example, the second network entity 910 may perform a block interleave operation to map the encoded information to one or more constellation symbols. For example, the block interleaver may be a depth-m block interleaver. In some aspects, the block interleave operation may be similar to the SBPM interleaving described in connection with FIG. 8.

As shown by reference number 940, the second network entity 910 may transmit, and the first network entity 905 may receive, a signal that indicates second information that is based on the one or more constellation symbols. For example, the second network entity 910 may convert the modulated constellation symbols into an RF signal that can be propagated through the wireless communication channel.

The first network entity 905 may receive the signal. The first network entity 905 may perform RF processing to obtain the encoded information. For example, the first network entity 905 may convert the received RF signal into baseband signals, which may include down-converting the signal frequency, filtering, and amplifying the signal to prepare the signal for further processing.

As shown by reference number 945, the first network entity 905 may demodulate the encoded information using a block interleaver, such as a depth-m block de-interleaver or SBPM de-interleaving. The demodulation operation may include the first network entity 905 mapping the received constellation symbols back to corresponding encoded bits. The block interleaver enables the first network entity 905 to rearrange the bits in a pattern that mitigates the effects of burst errors and ensures that bits with different levels of reliability are appropriately distributed, as described elsewhere herein.

As shown by reference number 950, the first network entity 905 may decode the encoded information to obtain decoded information (e.g., information bits). For example, the first network entity 905 may decode the encoded information using an LDPC decoder, such as the LDPC decoder 430. The LDPC decoder may operate by iteratively solving the parity-check equations defined by the base graph.

The first network entity 905 may decode the encoded information based on the permutation pattern. For example, the first network entity 905 may use a base graph that has re-ordered columns based on the permutation pattern, in a similar manner as described elsewhere herein. For example, the first network entity 905 may take into account the order or re-ordering of the columns of the base graph that was applied during the encoding process. By doing so, the first network entity 905 can accurately interpret the structure of the encoded bits and effectively correct any errors that may have occurred during transmission. This enables the LDPC code to maintain high error correction performance when the permutation pattern has been used to optimized to enhance the reliability of one or more bits within the modulation constellation.

As indicated above, FIG. 9 is provided as an example. Other examples may differ from what is described with respect to FIG. 9.

FIG. 10 is a diagram of an example 1000 associated with a permutation of a base graph for an LDPC code. As shown in FIG. 10, one or more columns of a base graph 1005 may be permuted to generated a permuted base graph 1010. FIG. 10 shows example PCMs for the base graph 1005 and the permuted base graph 1010. The permuted base graph 1010 may be used for an encoding operation, such as the encoding operation performed by the second network entity 910 as described in connection with reference number 930.

As shown in FIG. 10, the PCM for the base graph 1005 may include one or more parity columns 1015, such as core parity columns (e.g., the core parity columns 620). The one or more parity columns 1015 may represent variable nodes associated with the PCM of the base graph 1005. Additionally, the PCM for the base graph 1005 may include one or more punctured columns 1020, such as the punctured information columns 615. The one or more punctured columns 1020 may correspond to bits that are not transmitted, effectively increasing the code rate by reducing the number of transmitted bits. These punctured bits are inferred by the receiver during decoding using the redundancy provided by the other transmitted bits. Puncturing allows for flexible adaptation of the LDPC code to different data rates and channel conditions, enhancing the efficiency and robustness of the communication system.

As shown by reference number 1025, the PCM for the base graph 1005 may be permuted in accordance with a permutation pattern to generate the PCM for the permuted base graph 1010. For example, the columns of the PCM for the base graph 1005 may be re-ordered based on the permutation pattern to generate the PCM for the permuted base graph 1010. As an example, the one or more parity columns 1015 may be placed at the start of the PCM (e.g., shown in FIG. 10 as being placed before the one or more punctured columns 1020). The remaining columns of the PCM for the base graph 1005 may remain in the same order (e.g., with the one or more parity columns 1015 being moved to the start of the PCM). In other examples, the one or more parity columns 1015 may be placed directly after the one or more punctured columns 1020.

As shown in FIG. 10, by permuting the columns of the PCM for the base graph 1005, the one or more parity columns 1015 may be placed in a position that results in the bits corresponding to the one or more parity columns 1015 being mapped to an MSB 1030 of a constellation symbol. This permutation enhances the reliability of the parity bits, as the MSBs in a modulation constellation may be less susceptible to noise and errors compared to the LSBs. Consequently, mapping parity bits to MSBs improves the overall error correction performance of the LDPC code, leading to more robust and reliable communication.

As indicated above, FIG. 10 is provided as an example. Other examples may differ from what is described with respect to FIG. 10.

FIG. 11 is a diagram illustrating an example 1100 of redundancy versions. In some examples, a network entity, such as the second network entity 910, may apply redundancy version cycling to one or more repetitions to transmit different redundancy versions of the repetition in different transmission occasions.

“Redundancy version” (RV) of a repetition refers to a set of encoded bits that are transmitted for that repetition. Using RV cycling, the network entity transmits a different set of encoded bits in different PUSCH repetitions. For example, the network entity may store bits for an uplink transmission in a circular buffer 1105 (e.g., stored in memory of the network entity). The circular buffer 1105 stores information bits 1110 and parity bits 1115 (sometimes called parity-check bits). The information bits 1110 may include the data to be transmitted, and the parity bits 1115 may include linear combinations of the data (e.g., of the information bits 1110). The network entity may encode information bits 1110, parity bits 1115, or a combination of information bits 1110 and parity bits 1115 into a set of encoded bits, and may transmit the set of encoded bits. The particular bits that are selected to be included in the set of encoded bits for a repetition depend on (or are defined by) the RV of that repetition.

As an example, the starting bit locations may be defined by a table 1140, such as for HARQ using LDPC code, such as the QC-LDPC described herein. The table 1140 defines starting bit locations in the circular buffer 1105 for a first base graph (BG1) and a second base graph (BG2). A base graph may be used by the network entity for determining parity bits 1115 for a transmission based at least in part on a transport block (TB) size and a code rate (with BG1 being intended for TBs with a larger TB size, and BG2 being intended for TBs with a smaller TB size). Referring to the table, Ncb represents the length of the circular buffer 1105 (e.g., the number of bits included in the circular buffer 1105), and Zc represents a lifting factor.

In some aspects, different column permutation may be used on a base graph (or lifted graph) for different RVs. For example, the circular buffer 1105 and the RVs may be defined using an un-permuted base graph or coded bits. A different permutation pattern may be applied to the columns of the base graph (or lifted graph) for each RV. For example, each RV may have a unique permutation pattern that reorders the columns of the base graph differently, ensuring that the encoded bits are distributed in a way that optimizes error correction performance for each RV. As a result, overlapping bits between different RVs (e.g., bits that are transmitted in two or more RVs) may be mapped to different bit positions of a modulation constellation in different RVs. This may improve the overall reliability and robustness of the communication system by reducing the likelihood of persistent errors across multiple RVs, thereby enhancing the effectiveness of error correction, increasing channel diversity for the overlapping bits, or increasing the chances of successful data recovery at a receiver (such as the first network entity 905).

As indicated above, FIG. 11 is provided as an example. Other examples may differ from what is described with respect to FIG. 11.

FIG. 12 is a diagram illustrating an example of a Tx chain and an Rx chain per dimension in a PAS system. In some aspects, one or more components of the Tx chain may be implemented in a processing system, such as the processing system 110, the processing system 112, the processing system 240, or the processing system 245. As an example, the Tx chain shown in FIG. 12 may be implemented in the second network entity 910.

PAS, sometimes referred to as probabilistic constellation shaping (PCS), is a coded modulation technique in which constellation shaping is combined with channel coding. For example, in existing wireless networks, coherent transmission is typically based on QAM or other modulation techniques where data bits to be transmitted are encoded into a constellation in which each point is a unique combination of phase and amplitude. In QAM and other traditional modulation techniques, each constellation point has the same probability of being used, whereby outer constellation points that have a higher amplitude and consume more energy or power have the same probability of being used as inner constellation points that have a lower amplitude and consume less energy or power. In a system that uses PAS or PCS, referred to herein as a PAS system, lower energy/power constellations (e.g., inner points) may be used more frequently, enabling benefits such as enhanced granularity and improved noise tolerance. For example, in a PAS system, a distribution matching (DM) component may receive a uniform bit sequence with equal probabilities, and the DM component may convert the uniform bit sequence into symbols with a desired probability distribution (e.g., Gaussian). Accordingly, by using inner constellation points associated with a lower energy or a lower power more frequently than outer constellation points associated with a higher energy or a higher power, a PAS system may enable granular control over a number of bits per symbol and improved spectral efficiency with better noise tolerance or fewer nonlinearities relative to traditional QAM, among other examples.

For example, as shown in FIG. 12, the Tx chain in the PAS system may include a demultiplexer 1210 (shown as demux 1210), a distribution matcher 1220, an amplitudes-to-bits converter 1230, a forward error correction (FEC) encoder 1240, and a constellation mapping component 1250. As shown, the demultiplexer 1210 may receive a binary information string to be transmitted, and may provide an information string that includes k bits to the distribution matcher 1220, where k is a uniform input bit length for the distribution matcher 1220. As further shown, the distribution matcher 1220 may map the binary information string to positive amplitudes with a non-uniform distribution to produce an output n, where n is a shaped output in one dimension based on an amplitude-shift keying (ASK) sequence length. For example, the distribution matcher 1220 may map the binary information string to the positive amplitudes with the non-uniform distribution based on a DM rate (e.g., a shaping rate)

$${R}_{S} = \frac{k}{n}$$

or a Maxwell-Boltzmann distribution parameter (v) that can be mapped to a DM rate.

As further shown, the output n from the distribution matcher 1220 may be provided to the amplitude-to-bits converter 1230, which may convert the shaped output based on the ASK sequence length into (m−1)n bits, where m is log-2 of 2^{m}-ASK size (e.g., a number of bits per one dimension). The (m−1)n bits output from the amplitude-to-bits converter 1230 may be provided to the FEC encoder 1240 together with a γn-bit information string output by the demultiplexer 1210, where γ is a rate of one or more extra (e.g., uniform) data bits carried over one or more symbol signs. As further shown, the FEC encoder 1240 may generate (m−1)n shaped systematic bits based on the output from the amplitude-to-bits converter 1230, and may generate γn non-shaped systematic bits and (1−γ)n parity check bits based on the γn-bit information string output by the demultiplexer 1210. For example, as shown at 1245, the FEC encoder 1240 may generate the shaped systematic bits, the non-shaped systematic bits, or the parity check bits based on an FEC rate R_{c}=(m−1+γ)/m≥(m−1)/m. As further shown, the constellation mapping component 1250 may use the shaped systematic bits to generate transmit amplitudes A, and may further use the non-shaped systematic bits and the parity check bits to generate transmit sign bits S associated with the transmit amplitudes.

As further shown, probabilistically shaped channel inputs X=A·S may then be transmitted over a wireless channel 1260 that includes resources in a spatial domain (e.g., one or more layers), a frequency domain (e.g., one or more resource blocks (RBs) or frequency bands), and a time domain (e.g., one or more symbols or slots). For example, the probabilistically shaped channel inputs may be transmitted over the wireless channel 1260 at a transmission rate Rₜ=R_{S}+γ<H(A)+γ, where H is the wireless channel 1260.

In some aspects, the PAS system may include an Rx chain that can receive a signal transmitted over the wireless channel 1260. One or more components of the Rx chain may be implemented in a processing system, such as the processing system 110, the processing system 112, the processing system 240, or the processing system 245. As an example, the Rx chain shown in FIG. 12 may be implemented in the first network entity 905. As shown in FIG. 12, the Rx chain may include various components that perform an inverse function relative to the Tx chain. For example, the Rx chain may include a multiplexer 1210′ (shown as mux 1210′), a distribution dematcher 1220′, a bits-to-amplitudes converter 1230′, an FEC decoder 1240′, and a constellation demapping component 1250′ that may convert probabilistically shaped channel inputs into a received binary string.

In this way, the PAS system may enable more granular control over a number of bits per symbol and improved spectral efficiency with better noise tolerance or fewer nonlinearities relative to traditional QAM by using inner constellation points associated with a lower energy or a lower power more frequently than outer constellation points associated with a higher energy or a higher power. For example, on the transmit side (e.g., in the Tx chain), rate adaptation may be performed by tuning the DM parameters (e.g., the DM rate or Maxwell-Boltzmann distribution parameter) and the non-shaped information bits (γn). For example, the output from the distribution matcher 1220 is used to map the binary bits to be transmitted to positive amplitudes with a non-uniform distribution, and non-shaped information bits and parity bits are mapped to the sign(s) of the constellation, where uniformly distributed sign bits cause no change to the constellation distribution.

In some aspects, a permutation pattern applied for QC-LDPC encoding performed by the FEC encoder 1240 may be associated with PAS. For example, the FEC encoder 1240 may perform the encoding operation described herein, such as in connection with reference number 930. In some aspects, the permutation pattern may be configured such that the reliability level after the distribution matcher 1220 (at the input of FEC encoder 1240) is preserved by the permutation of the base graph (or lifted graph). For example, a network entity (e.g., the second network entity 910) may perform, using information, a PAS operation to obtain shaped information (e.g., shaped information bits). The network entity may encode (e.g., via the FEC encoder 1240) the shaped information to obtain encoded information (e.g., as described in connection with reference number 930) In some aspects, the permutation pattern used for the encoding operation is associated with (or specific to) scenarios where PAS is performed. For example, the shaped information may have reliability levels for respective constellation symbols from multiple constellation symbols. The permuted order of columns indicated by the permutation pattern may result in the encoded information having the reliability levels for the respective constellation symbols.

In some aspects, as shown in FIG. 12, the Tx chain may optionally include an interleaver 1270. The network entity (e.g., via the interleaver 1270) may perform, using the shaped information, an interleave operation to obtain interleaved information. The interleaver 1270 may perform the permutation based on the permutation pattern, as described in more detail elsewhere herein. The interleaver 1270 may re-order or interleave the shaped information (e.g., the shaped bits). In such examples, the interleaved information may have the reliability levels for the respective constellation symbols (e.g., the same reliability levels as the output of the distribution matcher 1220). The network entity (e.g., via the FEC encoder 1240) may encode, using a permuted order of a base graph (or lifted graph), the interleaved information to obtain the encoded information. This enables the network entity to match the reliability of the uncoded shaped bits to the reliability of the columns of the base graph. For example, the output of the interleaver 1270 may match a given reliability mapping, such as a reliability mapping for SBPM or another reliability mapping. The Rx chain may include a de-interleaver 1270′ for deinterleaving an output of the FEC decoder 1240′.

The number and arrangement of components shown in FIG. 12 are provided as an example. In practice, there may be additional components, fewer components, different components, or differently arranged components than those shown in FIG. 12. Furthermore, two or more components shown in FIG. 12 may be implemented within a single component, or a single component shown in FIG. 12 may be implemented as multiple, distributed components. Additionally, or alternatively, a set of components (e.g., one or more components) shown in FIG. 12 may perform one or more functions described as being performed by another set of components shown in FIG. 12.

FIG. 13 is a diagram illustrating an example process 1300 performed, for example, at a first network entity or an apparatus of a first network entity. Example process 1300 is an example where the apparatus or the first network entity (e.g., the second network entity 910) performs operations associated with permutations for a low-density parity check code.

As shown in FIG. 13, in some aspects, process 1300 may include encoding first information to obtain encoded information, wherein the permutation pattern is associated with columns of a base graph for a low-density parity check code (block 1310). For example, the first network entity (e.g., using communication manager 1506, depicted in FIG. 15) may encode first information to obtain encoded information, wherein the permutation pattern is associated with columns of a base graph for a low-density parity check code, as described above.

As further shown in FIG. 13, in some aspects, process 1300 may include modulating the encoded information to map the encoded information to one or more constellation symbols (block 1320). For example, the first network entity (e.g., using communication manager 1506, depicted in FIG. 15) may modulate the encoded information to map the encoded information to one or more constellation symbols, as described above.

As further shown in FIG. 13, in some aspects, process 1300 may include transmitting a signal that indicates second information that is based on the one or more constellation symbols (block 1330). For example, the first network entity (e.g., using transmission component 1504 or communication manager 1506, depicted in FIG. 15) may transmit a signal that indicates second information that is based on the one or more constellation symbols, as described above.

Process 1300 may include additional aspects, such as any single aspect or any combination of aspects described below or in connection with one or more other processes described elsewhere herein.

In a first aspect, the permutation pattern indicates a permuted order of the columns of the base graph.

In a second aspect, alone or in combination with the first aspect, the permutation pattern is based on at least one of the base graph, a modulation order associated with the signal, or a modulation and coding scheme associated with the signal.

In a third aspect, alone or in combination with one or more of the first and second aspects, the permutation pattern is based on the base graph and a modulation and coding scheme associated with the signal.

In a fourth aspect, alone or in combination with one or more of the first through third aspects, the permutation pattern is based on the base graph and a modulation order associated with the signal.

In a fifth aspect, alone or in combination with one or more of the first through fourth aspects, the permutation pattern is based on the base graph.

In a sixth aspect, alone or in combination with one or more of the first through fifth aspects, the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

In a seventh aspect, alone or in combination with one or more of the first through sixth aspects, the signal is associated with a redundancy version from multiple redundancy versions that are associated with the first information, and wherein encoding the first information includes encoding the first information to obtain multiple sets of encoded information for respective redundancy versions of the multiple redundancy versions, wherein the multiple permutation patterns are associated with the respective redundancy versions of the multiple redundancy versions.

In an eighth aspect, alone or in combination with one or more of the first through seventh aspects, encoding the first information includes performing a PAS operation to obtain shaped information, and wherein the permutation pattern is associated with PAS.

In a ninth aspect, alone or in combination with one or more of the first through eighth aspects, transmitting the signal includes transmitting the signal to a second network entity.

In a tenth aspect, alone or in combination with one or more of the first through ninth aspects, modulating the encoded information includes modulating the encoded information using a block interleave operation.

In an eleventh aspect, alone or in combination with one or more of the first through tenth aspects, the permutation pattern is associated with a lifted graph that is based on the base graph.

Although FIG. 13 shows example blocks of process 1300, in some aspects, process 1300 may include additional blocks, fewer blocks, different blocks, or differently arranged blocks than those depicted in FIG. 13. Additionally, or alternatively, two or more of the blocks of process 1300 may be performed in parallel.

FIG. 14 is a diagram illustrating an example process 1400 performed, for example, at a first network entity or an apparatus of a first network entity. Example process 1400 is an example where the apparatus or the first network entity (e.g., the first network entity 905) performs operations associated with permutations for a low-density parity check code.

As shown in FIG. 14, in some aspects, process 1400 may include receiving a signal that indicates first information associated with one or more constellation symbols (block 1410). For example, the first network entity (e.g., using reception component 1602 or communication manager 1606, depicted in FIG. 16) may receive a signal that indicates first information associated with one or more constellation symbols, as described above.

As further shown in FIG. 14, in some aspects, process 1400 may include demodulating the first information to obtain encoded information (block 1420). For example, the first network entity (e.g., using communication manager 1606, depicted in FIG. 16) may demodulate the first information to obtain encoded information, as described above.

As further shown in FIG. 14, in some aspects, process 1400 may include decoding the encoded information to obtain second information, wherein the permutation pattern is associated with columns of a base graph for a low-density parity check code (block 1430). For example, the first network entity (e.g., using communication manager 1606, depicted in FIG. 16) may decode the encoded information to obtain second information, wherein the permutation pattern is associated with columns of a base graph for a low-density parity check code, as described above.

Process 1400 may include additional aspects, such as any single aspect or any combination of aspects described below or in connection with one or more other processes described elsewhere herein.

In a first aspect, the permutation pattern indicates a permuted order of the columns of the base graph.

In a second aspect, alone or in combination with the first aspect, the permutation pattern is based on at least one of the base graph, a modulation order associated with the signal, or a modulation and coding scheme associated with the signal.

In a third aspect, alone or in combination with one or more of the first and second aspects, the permutation pattern is based on the base graph and a modulation and coding scheme associated with the signal.

In a fourth aspect, alone or in combination with one or more of the first through third aspects, the permutation pattern is based on the base graph and a modulation order associated with the signal.

In a fifth aspect, alone or in combination with one or more of the first through fourth aspects, the permutation pattern is based on the base graph.

In a sixth aspect, alone or in combination with one or more of the first through fifth aspects, the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

In a seventh aspect, alone or in combination with one or more of the first through sixth aspects, the signal is associated with a redundancy version from multiple redundancy versions that are associated with the first information, and wherein decoding the encoded information includes decoding the encoded information to obtain multiple sets of decoded information for respective redundancy versions of the multiple redundancy versions, wherein the multiple permutation patterns are associated with the respective redundancy versions of the multiple redundancy versions.

In an eighth aspect, alone or in combination with one or more of the first through seventh aspects, decoding the encoded information includes performing a de-shaping operation for PAS to obtain de-shaped information, and wherein the permutation pattern is associated with PAS.

In a ninth aspect, alone or in combination with one or more of the first through eighth aspects, receiving the signal includes receiving the signal from a second network entity.

In a tenth aspect, alone or in combination with one or more of the first through ninth aspects, demodulating the encoded information includes demodulating the encoded information using a block interleave operation.

In an eleventh aspect, alone or in combination with one or more of the first through tenth aspects, the permutation pattern is associated with a lifted graph that is based on the base graph.

Although FIG. 14 shows example blocks of process 1400, in some aspects, process 1400 may include additional blocks, fewer blocks, different blocks, or differently arranged blocks than those depicted in FIG. 14. Additionally, or alternatively, two or more of the blocks of process 1400 may be performed in parallel.

FIG. 15 is a diagram of an example apparatus 1500 for wireless communication. The apparatus 1500 may be a network entity, or a network entity may include the apparatus 1500. In some aspects, the apparatus 1500 includes a reception component 1502, a transmission component 1504, or a communication manager 1506, which may be in communication with one another (for example, via one or more buses or one or more other components). In some aspects, the communication manager 1506 is the communication manager 114, the communication manager 118, the communication manager 250, or the communication manager 255. As shown, the apparatus 1500 may communicate with another apparatus 1508, such as a UE or a network node (such as a CU, a DU, an RU, or a base station), using the reception component 1502 and the transmission component 1504. The communication manager 1506 may be included in, or implemented via, a processing system (for example, the processing system 110, the processing system 112, the processing system 240, or the processing system 245).

In some aspects, the apparatus 1500 may be configured to perform one or more operations described herein in connection with FIGS. 9-12. Additionally, or alternatively, the apparatus 1500 may be configured to perform one or more processes described herein, such as process 1300 of FIG. 13, or a combination thereof. In some aspects, the apparatus 1500 or one or more components shown in FIG. 15 may include one or more components described in connection with FIGS. 1-3. Additionally, or alternatively, one or more components shown in FIG. 15 may be implemented within one or more components described in connection with FIGS. 1-3. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1502 may receive communications, such as reference signals, control information, data communications, or a combination thereof, from the apparatus 1508. The reception component 1502 may provide received communications to one or more other components of the apparatus 1500. In some aspects, the reception component 1502 may perform signal processing on the received communications, and may provide the processed signals to the one or more other components of the apparatus 1500. In some aspects, the reception component 1502 may include one or more components described above in connection with FIGS. 1-3, such as a radio, one or more RF chains, one or more transceivers, or one or more modems, each of which may in turn be coupled with one or more antennas of the network entity.

The transmission component 1504 may transmit communications, such as reference signals, control information, data communications, or a combination thereof, to the apparatus 1508. In some aspects, one or more other components of the apparatus 1500 may generate communications and may provide the generated communications to the transmission component 1504 for transmission to the apparatus 1508. In some aspects, the transmission component 1504 may perform signal processing on the generated communications, and may transmit the processed signals to the apparatus 1508. In some aspects, the transmission component 1504 may include one or more components described in connection with FIGS. 1-3, such as a radio, one or more RF chains, one or more transceivers, or one or more modems, each of which may in turn be coupled with one or more antennas described in connection with FIGS. 1-3. In some aspects, the transmission component 1504 may be co-located with the reception component 1502.

The communication manager 1506 may support operations of the reception component 1502 or the transmission component 1504. For example, the communication manager 1506 may receive information associated with configuring reception of communications by the reception component 1502 or transmission of communications by the transmission component 1504. Additionally, or alternatively, the communication manager 1506 may generate or provide control information to the reception component 1502 or the transmission component 1504 to control reception or transmission of communications.

The communication manager 1506 may encode first information to obtain encoded information, wherein the permutation pattern is associated with columns of a base graph for a low-density parity check code. The communication manager 1506 may modulate the encoded information to map the encoded information to one or more constellation symbols. The transmission component 1504 may transmit a signal that indicates second information that is based on the one or more constellation symbols.

The number and arrangement of components shown in FIG. 15 are provided as an example. In practice, there may be additional components, fewer components, different components, or differently arranged components than those shown in FIG. 15. Furthermore, two or more components shown in FIG. 15 may be implemented within a single component, or a single component shown in FIG. 15 may be implemented as multiple, distributed components. Additionally, or alternatively, a set of (one or more) components shown in FIG. 15 may perform one or more functions described as being performed by another set of components shown in FIG. 15.

FIG. 16 is a diagram of an example apparatus 1600 for wireless communication. The apparatus 1600 may be a network entity, or a network entity may include the apparatus 1600. In some aspects, the apparatus 1600 includes a reception component 1602, a transmission component 1604, or a communication manager 1606, which may be in communication with one another (for example, via one or more buses or one or more other components). In some aspects, the communication manager 1606 is the communication manager 114, the communication manager 118, the communication manager 250, or the communication manager 255. As shown, the apparatus 1600 may communicate with another apparatus 1608, such as a UE or a network node (such as a CU, a DU, an RU, or a base station), using the reception component 1602 and the transmission component 1604. The communication manager 1606 may be included in, or implemented via, a processing system (for example, the processing system 110, the processing system 112, the processing system 240, or the processing system 245).

In some aspects, the apparatus 1600 may be configured to perform one or more operations described herein in connection with FIGS. 9-12. Additionally, or alternatively, the apparatus 1600 may be configured to perform one or more processes described herein, such as process 1400 of FIG. 14, or a combination thereof. In some aspects, the apparatus 1600 or one or more components shown in FIG. 16 may include one or more components described in connection with FIGS. 1-3. Additionally, or alternatively, one or more components shown in FIG. 16 may be implemented within one or more components described in connection with FIGS. 1-3. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1602 may receive communications, such as reference signals, control information, data communications, or a combination thereof, from the apparatus 1608. The reception component 1602 may provide received communications to one or more other components of the apparatus 1600. In some aspects, the reception component 1602 may perform signal processing on the received communications, and may provide the processed signals to the one or more other components of the apparatus 1600. In some aspects, the reception component 1602 may include one or more components described in connection with FIGS. 1-3, such as a radio, one or more RF chains, one or more transceivers, or one or more modems, each of which may in turn be coupled with one or more antennas of the network entity.

The transmission component 1604 may transmit communications, such as reference signals, control information, data communications, or a combination thereof, to the apparatus 1608. In some aspects, one or more other components of the apparatus 1600 may generate communications and may provide the generated communications to the transmission component 1604 for transmission to the apparatus 1608. In some aspects, the transmission component 1604 may perform signal processing on the generated communications, and may transmit the processed signals to the apparatus 1608. In some aspects, the transmission component 1604 may include one or more components described in connection with FIGS. 1-3, such as a radio, one or more RF chains, one or more transceivers, or one or more modems, each of which may in turn be coupled with one or more antennas described in connection with FIGS. 1-3. In some aspects, the transmission component 1604 may be co-located with the reception component 1602.

The communication manager 1606 may support operations of the reception component 1602 or the transmission component 1604. For example, the communication manager 1606 may receive information associated with configuring reception of communications by the reception component 1602 or transmission of communications by the transmission component 1604. Additionally, or alternatively, the communication manager 1606 may generate or provide control information to the reception component 1602 or the transmission component 1604 to control reception or transmission of communications.

The reception component 1602 may receive a signal that indicates first information associated with one or more constellation symbols. The communication manager 1606 may demodulate the first information to obtain encoded information. The communication manager 1606 may decode the encoded information to obtain second information, wherein the permutation pattern is associated with columns of a base graph for a low-density parity check code.

The number and arrangement of components shown in FIG. 16 are provided as an example. In practice, there may be additional components, fewer components, different components, or differently arranged components than those shown in FIG. 16. Furthermore, two or more components shown in FIG. 16 may be implemented within a single component, or a single component shown in FIG. 16 may be implemented as multiple, distributed components. Additionally, or alternatively, a set of (one or more) components shown in FIG. 16 may perform one or more functions described as being performed by another set of components shown in FIG. 16.

The following provides an overview of some Aspects of the present disclosure:

Aspect 1: A method of wireless communication performed by a first network entity, comprising: encoding, based on a permutation pattern, first information to obtain encoded information, wherein the permutation pattern is associated with columns of a base graph for a low-density parity check code; modulating the encoded information to map the encoded information to one or more constellation symbols; and transmitting a signal that indicates second information that is based on the one or more constellation symbols.

Aspect 2: The method of Aspect 1, wherein the permutation pattern indicates a permuted order of the columns of the base graph.

Aspect 3: The method of Aspect 2, wherein the permuted order includes one or more parity columns of the base graph at a start of the base graph.

Aspect 4: The method of Aspect 3, wherein the one or more parity columns are one or more core parity columns.

Aspect 5: The method of any of Aspects 3-4, wherein the one or more parity columns are associated with at least a portion of second degree parity columns included in the base graph.

Aspect 6: The method of any of Aspects 3-5, wherein the one or more parity columns are associated with one or more first degree parity columns included in the base graph.

Aspect 7: The method of any of Aspects 2-6, wherein the permuted order includes one or more parity columns directly after one or more punctured columns of the base graph.

Aspect 8: The method of any of Aspects 2-7, wherein encoding the first information comprises: obtaining a codeword that is based on the first information and the permuted order of the columns of the base graph; and wherein modulating the encoded information comprises: performing an interleave operation using the codeword to map the encoded information to the one or more constellation symbols.

Aspect 9: The method of Aspect 8, wherein the interleave operation is a block interleave operation.

Aspect 10: The method of any of Aspects 1-9, wherein the permutation pattern is based on at least one of: the base graph, a modulation order associated with the signal, or a modulation and coding scheme associated with the signal.

Aspect 11: The method of any of Aspects 1-10, wherein the permutation pattern is based on the base graph and a modulation and coding scheme associated with the signal.

Aspect 12: The method of any of Aspects 1-11, wherein the permutation pattern is based on the base graph and a modulation order associated with the signal.

Aspect 13: The method of any of Aspects 1-12, wherein the permutation pattern is based on the base graph.

Aspect 14: The method of any of Aspects 1-13, wherein the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

Aspect 15: The method of any of Aspects 1-14, wherein the signal is associated with a redundancy version from multiple redundancy versions that are associated with the first information, and wherein encoding the first information comprises: encoding, using multiple permutation patterns including the permutation pattern, the first information to obtain multiple sets of encoded information for respective redundancy versions of the multiple redundancy versions, wherein the multiple permutation patterns are associated with the respective redundancy versions of the multiple redundancy versions.

Aspect 16: The method of any of Aspects 1-15, wherein encoding the first information comprises: performing, using the first information, a probabilistic amplitude shaping (PAS) operation to obtain shaped information, and wherein the permutation pattern is associated with PAS.

Aspect 17: The method of Aspect 16, wherein the shaped information has reliability levels for respective constellation symbols from multiple constellation symbols including the one or more constellation symbols, and wherein encoding the first information comprises: encoding, using a permuted order of the base graph, the shaped information to obtain the encoded information, wherein the permuted order is indicated by the permutation pattern, and wherein the encoded information has the reliability levels for the respective constellation symbols.

Aspect 18: The method of Aspect 16, wherein the shaped information has reliability levels for respective constellation symbols from multiple constellation symbols including the one or more constellation symbols, and wherein encoding the first information comprises: performing, using the shaped information, an interleave operation to obtain interleaved information, wherein the interleaved information has the reliability levels for the respective constellation symbols; and encoding, using a permuted order of the base graph, the interleaved information to obtain the encoded information, wherein the permuted order is indicated by the permutation pattern.

Aspect 19: The method of any of Aspects 1-18, wherein transmitting the signal comprises transmitting the signal to a second network entity.

Aspect 20: The method of any of Aspects 1-19, wherein modulating the encoded information comprises modulating the encoded information using a block interleave operation.

Aspect 21: The method of any of Aspects 1-20, wherein the permutation pattern is associated with a lifted graph that is based on the base graph.

Aspect 22: A method of wireless communication performed by a first network entity, comprising: receiving a signal that indicates first information associated with one or more constellation symbols; demodulating, based on the one or more constellation symbols, the first information to obtain encoded information; and decoding, based on a permutation pattern, the encoded information to obtain second information, wherein the permutation pattern is associated with columns of a base graph for a low-density parity check code.

Aspect 23: The method of Aspect 22, wherein the permutation pattern indicates a permuted order of the columns of the base graph.

Aspect 24: The method of Aspect 23, wherein the permuted order includes one or more parity columns of the base graph at a start of the base graph.

Aspect 25: The method of Aspect 24, wherein the one or more parity columns are one or more core parity columns.

Aspect 26: The method of any of Aspects 24-25, wherein the one or more parity columns are associated with at least a portion of second degree parity columns included in the base graph.

Aspect 27: The method of any of Aspects 24-26, wherein the one or more parity columns are associated with one or more first degree parity columns included in the base graph.

Aspect 28: The method of any of Aspects 23-27, wherein the permuted order includes one or more parity columns directly after one or more punctured columns of the base graph.

Aspect 29: The method of any of Aspects 23-28, wherein demodulating the first information comprises: performing a deinterleave operation to map the one or more constellation symbols to a codeword; and wherein decoding the encoded information comprises decoding the codeword to obtain the first information based on the permuted order of the columns of the base graph.

Aspect 30: The method of any of Aspects 22-29, wherein the permutation pattern is based on at least one of: the base graph, a modulation order associated with the signal, or a modulation and coding scheme associated with the signal.

Aspect 31: The method of any of Aspects 22-30, wherein the permutation pattern is based on the base graph and a modulation and coding scheme associated with the signal.

Aspect 32: The method of any of Aspects 22-31, wherein the permutation pattern is based on the base graph and a modulation order associated with the signal.

Aspect 33: The method of any of Aspects 22-32, wherein the permutation pattern is based on the base graph.

Aspect 34: The method of any of Aspects 22-33, wherein the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

Aspect 35: The method of any of Aspects 22-34, wherein the signal is associated with a redundancy version from multiple redundancy versions that are associated with the first information, and wherein decoding the encoded information comprises: decoding, using multiple permutation patterns including the permutation pattern, the encoded information to obtain multiple sets of decoded information for respective redundancy versions of the multiple redundancy versions, wherein the multiple permutation patterns are associated with the respective redundancy versions of the multiple redundancy versions.

Aspect 36: The method of any of Aspects 22-35, wherein decoding the encoded information comprises: performing, using the encoded information, a de-shaping operation for probabilistic amplitude shaping (PAS) to obtain de-shaped information, and wherein the permutation pattern is associated with PAS.

Aspect 37: The method of Aspect 36, wherein the de-shaped information has reliability levels for respective constellation symbols from multiple constellation symbols including the one or more constellation symbols, and wherein decoding the encoded information comprises: decoding, using a permuted order of the base graph, the de-shaped information to obtain the second information, wherein the permuted order is indicated by the permutation pattern, and wherein the second information has the reliability levels for the respective constellation symbols.

Aspect 38: The method of Aspect 36, wherein the de-shaped information has reliability levels for respective constellation symbols from multiple constellation symbols including the one or more constellation symbols, and wherein decoding the encoded information comprises: decoding, using a permuted order of the base graph, the encoded information to obtain the decoded information, wherein the permuted order is indicated by the permutation pattern; and performing, using the decoded information, a deinterleave operation to obtain the second information, wherein the second information has the reliability levels for the respective constellation symbols.

Aspect 39: The method of any of Aspects 22-38, wherein receiving the signal comprises receiving the signal from a second network entity.

Aspect 40: The method of any of Aspects 22-39, wherein demodulating the encoded information comprises demodulating the encoded information using a block interleave operation.

Aspect 41: The method of any of Aspects 22-40, wherein the permutation pattern is associated with a lifted graph that is based on the base graph.

Aspect 42: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-41.

Aspect 43: An apparatus for wireless communication at a device, the apparatus comprising one or more memories and one or more processors coupled to the one or more memories, the one or more processors configured to cause the device to perform the method of one or more of Aspects 1-41.

Aspect 44: An apparatus for wireless communication, the apparatus comprising at least one means for performing the method of one or more of Aspects 1-41.

Aspect 45: A non-transitory computer-readable medium storing code for wireless communication, the code comprising instructions executable by one or more processors to perform the method of one or more of Aspects 1-41.

Aspect 46: A non-transitory computer-readable medium storing a set of instructions for wireless communication, the set of instructions comprising one or more instructions that, when executed by one or more processors of a device, cause the device to perform the method of one or more of Aspects 1-41.

Aspect 47: A device for wireless communication, the device comprising a processing system that includes one or more processors and one or more memories coupled with the one or more processors, the processing system configured to cause the device to perform the method of one or more of Aspects 1-41.

Aspect 48: An apparatus for wireless communication at a device, the apparatus comprising one or more memories and one or more processors coupled to the one or more memories, the one or more processors individually or collectively configured to cause the device to perform the method of one or more of Aspects 1-41.

Aspect 49: A device comprising a processing system that includes one or more processors and one or more code-storing memories coupled with the one or more processors, the processing system configured to cause the device to perform the method of one or more of Aspects 1-41.

Aspect 50: A device comprising a processing system that includes processor circuitry and code-storing memory circuitry, the processing system configured to cause the device to perform the method of one or more of Aspects 1-41.

Aspect 51: A non-transitory computer-readable having code stored thereon that, when executed by one or more processors of a device, causes the device to perform the method of one or more of Aspects 1-41.

Aspect 52: A device for wireless communication, the device comprising a processing system configured to perform the method of one or more of Aspects 1-41.

Systems or methods described herein may be implemented in different forms of hardware or a combination of hardware and software. A component being configured to perform a function means that the component has a capability to perform the function, and does not require the function to be actually performed by the component, unless noted otherwise.

As used herein, the term “determine” or “determining” can encompass one or more of a wide variety of actions. For example, “determining” can include one or more of calculating, computing, processing, deriving, detecting, estimating, investigating, looking up, inferring, ascertaining, measuring, resolving, selecting, choosing, obtaining, identifying, interpreting, demodulating, decoding, reading, establishing, forming or generating, among other examples. In some such examples, determining can involve a processor performing some type of calculating, computing, deriving, estimating, inferring, ascertaining, resolving, predicting or other processing to obtain one or more numerical values, sets, elements or other information or results. In some other such examples, determining can involve a processor identifying, looking up, investigating or otherwise obtaining some type of value, set, element or other information or result from a table, a data structure, a database or other memory device or location. In some other such examples, determining can involve a processor identifying, interpreting, demodulating, decoding, detecting, reading or otherwise obtaining some type of value, set, element or other information or result signaled in, for example, a received wireless packet. In some other such examples, determining can involve a processor selecting or choosing one or more values, sets, elements or other information or results from a larger set of values, sets elements or other information or results. In some other such examples, determining can involve a processor performing a measurement, such as on a received signal.

As used herein, the articles “a” and “an” are intended to refer to one or more items and may be used interchangeably with “one or more” or “at least one.” As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Additionally, as used herein, a “set” can refer to one or more items, and a “subset” can refer to a whole set or less than the whole set, but not an empty set. “Set,” “group,” and similar terms are intended to include one or more items and may be used interchangeably with “one or more.” Furthermore, as used herein, the term “or” is intended to be interpreted in the inclusive sense (such as when referring to a series) and may be used interchangeably with “and/or,” unless otherwise explicitly indicated (for example, if used in conjunction with “either” or “only one of”). For example, “A or B” may include A only, B only, or a combination of A and B. Also, as used herein, the terms “has,” “have,” “having,” “comprise,” “comprising,” “include” and “including,” and derivatives thereof or similar terms are intended to be open-ended terms that do not limit an element that they modify (for example, an element “having” A also may have B).

As used herein, the phrase “associated with” is to be interpreted in the inclusive sense, unless otherwise explicitly indicated. For example, the phrase “associated with” is not to be construed as a reference to a closed set of conditions, factors, criteria, elements, components, or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components, or actions, among other examples. In various examples, the phrase “associated with” may be interpreted to mean “in association with,” “in accordance with,” “based on,” “based at least in part on,” “as a function of,” “in response to,” “responsive to,” or “using” as appropriate in the relevant context unless otherwise explicitly indicated. Furthermore, what follows the phrase “associated with,” “in association with,” “in accordance with,” “based on,” “based at least in part on,” “as a function of,” “in response to,” “responsive to,” or “using” is not necessarily the focal point or primary factor associated with the limitation preceding the phrase.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. Many of these features may be combined in ways not specifically recited in the claims or disclosed in the specification. The disclosure of various aspects includes each dependent claim in combination with every other claim in the claim set.

What is claimed is:

1. A first network entity, comprising:
a processing system configured to:
encode, based on a permutation pattern, first information to obtain encoded information, wherein the permutation pattern is associated with columns of a base graph for a low-density parity check code;
modulate the encoded information to map the encoded information to one or more constellation symbols; and
transmit a signal that indicates second information that is based on the one or more constellation symbols.

2. The first network entity of claim 1, wherein the permutation pattern indicates a permuted order of the columns of the base graph.

3. The first network entity of claim 2, wherein the permuted order includes one or more parity columns of the base graph at a start of the base graph.

4. The first network entity of claim 3, wherein the one or more parity columns are one or more core parity columns.

5. The first network entity of claim 3, wherein the one or more parity columns are associated with at least a portion of second degree parity columns included in the base graph.

6. The first network entity of claim 3, wherein the one or more parity columns are associated with one or more first degree parity columns included in the base graph.

7. The first network entity of claim 2, wherein the permuted order includes one or more parity columns directly after one or more punctured columns of the base graph.

8. The first network entity of claim 2, wherein, to encode the first information, the processing system is configured to:
obtain a codeword that is based on the first information and the permuted order of the columns of the base graph; and
wherein, to modulate the encoded information, the processing system is configured to:
perform an interleave operation using the codeword to map the encoded information to the one or more constellation symbols.

9. The first network entity of claim 1, wherein the permutation pattern is based on at least one of:
the base graph,
a modulation order associated with the signal, or
a modulation and coding scheme associated with the signal.

10. The first network entity of claim 1, wherein the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

11. The first network entity of claim 1, wherein the signal is associated with a redundancy version from multiple redundancy versions that are associated with the first information, and wherein, to encode the first information, the processing system is configured to:
encode, using multiple permutation patterns including the permutation pattern, the first information to obtain multiple sets of encoded information for respective redundancy versions of the multiple redundancy versions, wherein the multiple permutation patterns are associated with the respective redundancy versions of the multiple redundancy versions.

12. The first network entity of claim 1, wherein, to encode the first information, the processing system is configured to:
perform, using the first information, a probabilistic amplitude shaping (PAS) operation to obtain shaped information, and wherein the permutation pattern is associated with PAS.

13. The first network entity of claim 12, wherein the shaped information has reliability levels for respective constellation symbols from multiple constellation symbols including the one or more constellation symbols, and wherein, to encode the first information, the processing system is configured to:
encode, using a permuted order of the base graph, the shaped information to obtain the encoded information, wherein the permuted order is indicated by the permutation pattern, and wherein the encoded information has the reliability levels for the respective constellation symbols.

14. The first network entity of claim 12, wherein the shaped information has reliability levels for respective constellation symbols from multiple constellation symbols including the one or more constellation symbols, and wherein, to encode the first information, the processing system is configured to:
perform, using the shaped information, an interleave operation to obtain interleaved information, wherein the interleaved information has the reliability levels for the respective constellation symbols; and
encode, using a permuted order of the base graph, the interleaved information to obtain the encoded information, wherein the permuted order is indicated by the permutation pattern.

15. The first network entity of claim 1, wherein, to modulate the encoded information, the processing system is configured to modulate the encoded information using a block interleave operation.

16. The first network entity of claim 1, wherein the permutation pattern is associated with a lifted graph that is based on the base graph.

17. A first network entity, comprising:
a processing system configured to:
receive a signal that indicates first information associated with one or more constellation symbols;
demodulate, based on the one or more constellation symbols, the first information to obtain encoded information; and
decode, based on a permutation pattern, the encoded information to obtain second information, wherein the permutation pattern is associated with columns of a base graph for a low-density parity check code.

18. The first network entity of claim 17, wherein the permutation pattern is based on the base graph and a modulation and coding scheme associated with the signal.

19. The first network entity of claim 17, wherein the permutation pattern is based on the base graph and a modulation order associated with the signal.

20. The first network entity of claim 17, wherein the permutation pattern is based on the base graph.

21. The first network entity of claim 17, wherein the permutation pattern is associated with one or more base graph and modulation and coding scheme pairs, wherein the permutation pattern is associated with the base graph based on the signal being associated with a base graph and modulation and coding scheme pair included in the one or more base graph and modulation and coding scheme pairs.

22. The first network entity of claim 17, wherein the signal is associated with a redundancy version from multiple redundancy versions that are associated with the first information, and wherein, to decode the encoded information, the processing system is configured to:
decode, using multiple permutation patterns including the permutation pattern, the encoded information to obtain multiple sets of decoded information for respective redundancy versions of the multiple redundancy versions, wherein the multiple permutation patterns are associated with the respective redundancy versions of the multiple redundancy versions.

23. The first network entity of claim 17, wherein, to decode the encoded information, the processing system is configured to:
perform, using the encoded information, a de-shaping operation for probabilistic amplitude shaping (PAS) to obtain de-shaped information, and wherein the permutation pattern is associated with PAS.

24. The first network entity of claim 23, wherein the de-shaped information has reliability levels for respective constellation symbols from multiple constellation symbols including the one or more constellation symbols, and wherein, to decode the encoded information, the processing system is configured to:
decode, using a permuted order of the base graph, the de-shaped information to obtain the second information, wherein the permuted order is indicated by the permutation pattern, and wherein the second information has the reliability levels for the respective constellation symbols.

25. The first network entity of claim 23, wherein the de-shaped information has reliability levels for respective constellation symbols from multiple constellation symbols including the one or more constellation symbols, and wherein, to decode the encoded information, the processing system is configured to:
decode, using a permuted order of the base graph, the encoded information to obtain the decoded information, wherein the permuted order is indicated by the permutation pattern; and
perform, using the decoded information, a deinterleave operation to obtain the second information, wherein the second information has the reliability levels for the respective constellation symbols.
